(19) United States
(12) Patent Application Publication
(10) Pub. No.: US 2014/0225082 A1
(43) Pub. Date: Aug. 14, 2014

(54) ORGANIC LIGHT-EMITTING DIODE

(71) Applicant: Samsung Display Co., Ltd., Yongin-City (KR)

(72) Inventors: Soo-Jin PARK, Yongin-City (KR); Ji-Hye SHIM, Yongin-City (KR); Suk KIM, Yongin-City (KR); Tsuyoshi NAIJO, Yongin-City (KR); Keon-Ha CHOI, Yongin-City (KR); Dong-Hyun KIM, Yongin-City (KR)

(73) Assignee: SAMSUNG DISPLAY CO., LTD., Yongin-City (KR)

(21) Appl. No.: 14/033,559

(22) Filed: Sep. 23, 2013

(30) Foreign Application Priority Data
Feb. 8, 2013 (KR) 10-2013-0014648

(51) Int. Cl. H01L 51/00

(52) U.S. Cl. CPC H01L 51/0067; H01L 51/0072
USPC 257/40

(57) ABSTRACT

An organic light-emitting diode including a substrate; a first electrode on the substrate; a second electrode disposed opposite to the first electrode; an emission layer disposed between the first electrode and second electrode; and a first interlayer, a first hole transport layer, a second interlayer and a second hole transport layer disposed between the first electrode and the emission layer, wherein the first interlayer, the first hole transport layer, the second interlayer, and the second hole transport layer are stacked from the first electrode in order, and wherein the first interlayer and the second interlayer each independently include an n-type semiconductor material.

### CROSS-REFERENCE TO RELATED PATENT APPLICATION

Korean Patent Application No. 10-2013-0014648, filed on Feb. 8, 2013, in the Korean Intellectual Property Office, is incorporated herein its entirety by reference.

### BACKGROUND

1. Field

Embodiments relate to an organic light-emitting diode.

2. Description of the Related Art

Organic light emitting diodes (OLEDs), which are self-emitting diodes, have advantages such as wide viewing angles, excellent contrast, quick response, high brightness, and excellent driving voltage characteristics, and can provide multicolored images.

A typical OLED has a structure including a substrate and an anode formed on the substrate, and a hole transport layer (HTL), an emission layer (EML), an electron transport layer (ETL), and a cathode that are sequentially stacked on the substrate. In this regard, the HTL, EML, and ETL are organic thin films formed of organic compounds.

An operating principle of an OLED having the above-described structure is as follows.

When a voltage is applied between the anode and cathode, holes injected from the anode move to the EML via the HTL, and electrons injected from the cathode move to the EML via the ETL. Carriers such as the holes and electrons recombine in the EML to generate excitons. When the excitons drop from an excited state to a ground state, light is emitted.

### SUMMARY

Embodiments are directed to an organic light-emitting diode (OLED).

There is provided an organic light-emitting diode comprising:

a substrate; a first electrode on the substrate; a second electrode disposed opposite to the first electrode; an emission layer disposed between the first electrode and second electrode; and a first interlayer, a first hole transport layer, a second interlayer and a second hole transport layer disposed between the first electrode and the emission layer,

wherein the first interlayer, the first hole transport layer, the second interlayer, and the second hole transport layer are stacked from the first electrode in order, and

wherein the first interlayer and the second interlayer each independently comprise an n-type semiconductor material.

### BRIEF DESCRIPTION OF THE DRAWING

Features will be apparent to those of skill in the art by describing in detail exemplary embodiments with reference to the attached drawing in which:

FIG. 1 illustrates a cross-sectional view of the structure of an organic light-emitting diode according to an embodiment.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

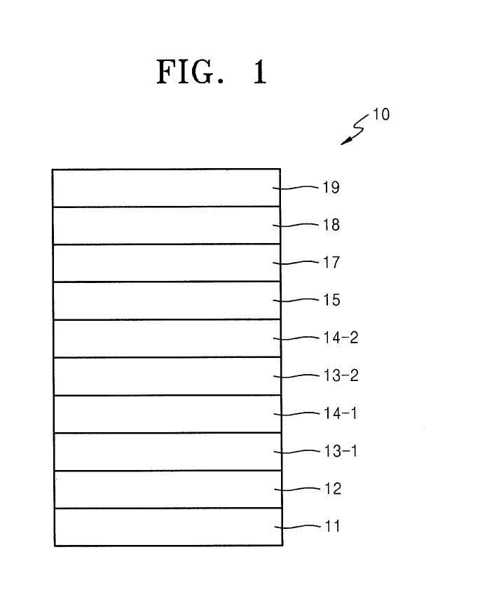

FIG. 1 illustrates a cross-sectional view of the structure of an organic light-emitting diode according to an embodiment.

The OLED 10 has a structure including a substrate 11, and a first electrode 12, a first interlayer 13-1, a first hole transport layer 14-1, a second interlayer 13-2, a second hole transport layer 14-2, an emission layer 15, an electron transport layer 17, an electron injection layer 18, and a second electrode 19 that are sequentially stacked on the substrate.

As illustrated in FIG. 1, the first electrode 12 and the first interlayer 13-1 are directly in contact, the first interlayer 13-1 and the first hole transport layer 14-1 are directly in contact, the first hole transport layer 14-1 and the second interlayer 13-2 are directly in contact, the second interlayer 13-2 and the second hole transport layer 14-2 are directly in contact, and finally the second hole transport layer 14-2 and the emission layer 15 are directly in contact.

A substrate 11 may be any substrate that is used in an existing OLED. In some embodiments, the substrate 11 may be a glass substrate or a transparent plastic substrate with strong mechanical strength, thermal stability, transparency, surface smoothness, east of handling, and water resistance.

The first electrode 12 may be formed by depositing or sputtering a first electrode-forming material on the substrate 11. When the first electrode 12 is an anode, the material for the first electrode may be selected from materials with a high work function to enable ease of hole injection. The first electrode 12 may be a reflective electrode or a transmission electrode. The material for the first electrode may be a transparent material with high conductivity, and examples of such materials are indium tin oxide (ITO), indium zinc oxide (IZO), tin oxide (SnO₂), and zinc oxide (ZnO). When magnesium (Mg), aluminum (Al), aluminum-lithium (Al—Li), calcium (Ca), magnesium-indium (Mg—In), magnesium-silver (Mg—Ag), or the like is used, the first electrode 12 may be used as a reflective electrode.

The first electrode 12 may have a single-layer structure or a multi-layer structure including at least two layers. For example, the first electrode 12 may have a three-layered structure of ITO/Ag/ITO, but is not limited thereto.

The first electrode 12 may be a hole injection electrode (anode).

The first interlayer 13-1 may be formed on the first electrode 12, and the second interlayer 13-2 may be formed on first hole transport layer 14-1. The first interlayer 13-1 and the second interlayer 13-2 may lower hole injection barriers at the first electrode 12 and the first hole transport layer 14-1 so that holes injected therethrough may migrate to the EML 15 more efficiently.

The first interlayer 13-1 and the second interlayer 13-2 may include n-type semiconductor materials.

For example, the first interlayer 13-1 and the second interlayer 13-2 may each independently include at least one selected from a hexaazatriphenylene based compound and a cyano group-containing compound.

The hexaazatriphenylene-based compound may be represented by Formula 40, below.

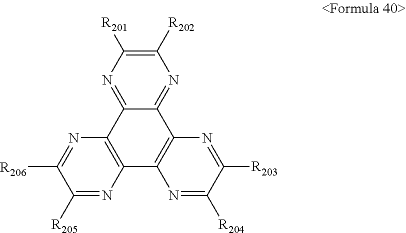

In Formula 40, R₂₀₁ to R₂₀₆ may be each independently selected from:

a hydrogen atom, a deuterium atom, a halogen atom, a cyano group (—CN), a nitro group (—NO₃), —SO₂R₂₁₀, —SOR₂₁—SO₃R₂₁₂, —COOR₂₁₃, —CONHR₂₁₄, —CONR₂₁₅R₂₁₆, a C₁-C₂₀ alkyl group, a C₁-C₂₀ alkoxy group, a C₂-C₂₀ alkenyl group, a C₆-C₃₀ aryl group, and a C₂-C₃₀ heteroaryl group; and/or

a C₁-C₂₀ alkyl group, a C₁-C₂₀ alkoxy group, a C₂-C₂₀ alkenyl group, a C₆-C₃₀ aryl group, and/or a C₂-C₃₀ heteroaryl group, each substituted with at least one of a deuterium atom, a halogen atom, a cyano group (—CN), and a nitro group (—NO₃); and

R₂₁₀ to R₂₁₆ may be each independently selected from a C₁-C₂₀ alkyl group, a C₁-C₂₀ alkoxy group, a C₂-C₂₀ alkenyl group, a C₆-C₃₀ aryl group, and/or a C₂-C₃₀ heteroaryl group.

For example, in Formula 40 above, R₂₀₁ to R₂₀₆ may be each independently selected from:

a hydrogen atom, a deuterium atom, a halogen atom, a cyano group (—CN), a nitro group (—NO₃), —SO₂R₂₁₀, —SOR₂₁₁, —SO₃R₂₁₂, —COOR₂₁₃, —CONHR₂₁₄, —CONR₂₁₅R₂₁₆, a C₁-C₁₀ alkyl group, a C₁-C₁₀ alkoxy group, a C₂-C₁₀ alkenyl group, a phenyl group, a naphthyl group, an anthryl group, a pyridinyl group, a pyrimidinyl group, and/or a triazinyl group; and/or

a C₁-C₂₀ alkyl group, a C₁-C₂₀ alkoxy group, a phenyl group, a naphthyl group, an anthryl group, a pyridinyl group, a pyrimidinyl group, and/or a triazinyl group, each substituted with at least one of a deuterium atom, a halogen atom, a cyano group (—CN), and a nitro group (—NO₃); and

R₂₁₀ to R₂₁₆ may be independently selected from a C₁-C₁₀ alkyl group, a C₁-C₁₀ alkoxy group, a C₂-C₁₀ alkenyl group, a phenyl group, a naphthyl group, an anthryl group, a pyridinyl group, a pyrimidinyl group, and/or a triazinyl group, but is not limited thereto.

In an implementation, the hexaazatriphenylene based compound may be one of Compounds 40A to 40E below, but is not limited thereto:

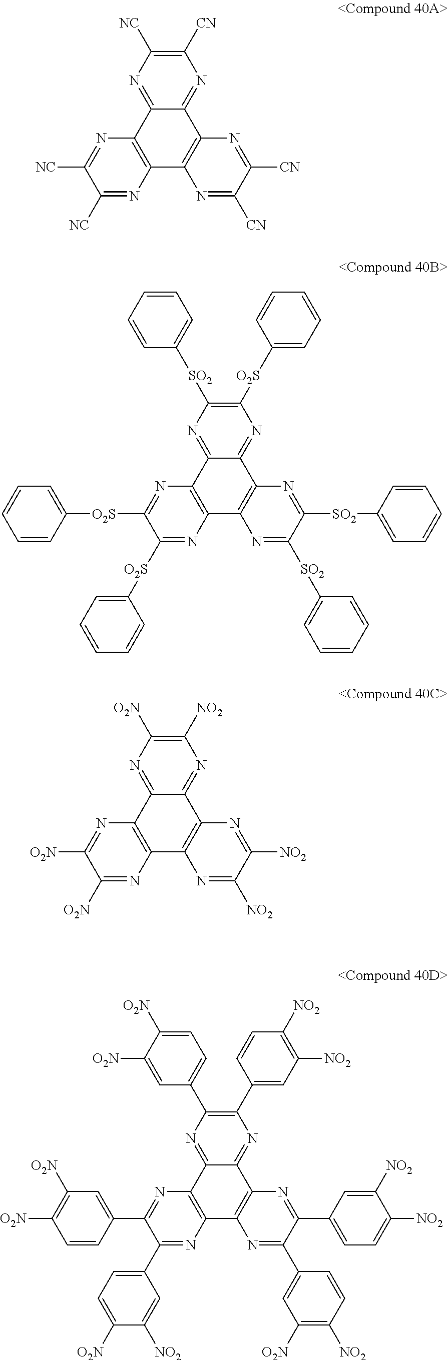

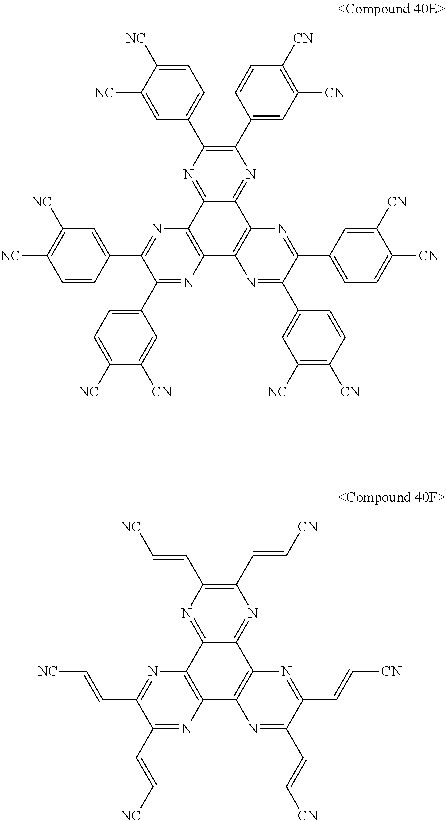 [SMILES: N#Cc1ccc(-c2nc3c4nc(-c5ccc(C#N)c(C#N)c5)c(-c5ccc(C#N)c(C#N)c5)nc4c4nc(-c5ccc(C#N)c(C#N)c5)c(-c5ccc(C#N)c(C#N)c5)nc4c3nc2-c2ccc(C#N)c(C#N)c2)cc1C#N ; N#C/C=C/c1nc2c3nc(/C=C/C#N)c(/C=C/C#N)nc3c3nc(/C=C/C#N)c(/C=C/C#N)nc3c2nc1/C=C/C#N]

The cyano group-containing compound may include two types of reduction forms of a primary electron. Thus, the cyano group-containing compound may have an expanded π-electromagnetic field (wherein, for example, measured by cyclic voltammetry) capcable of generating a stable radical.

The cyano group-containing compound may be represented by one of Formulas 1 to 20, below.

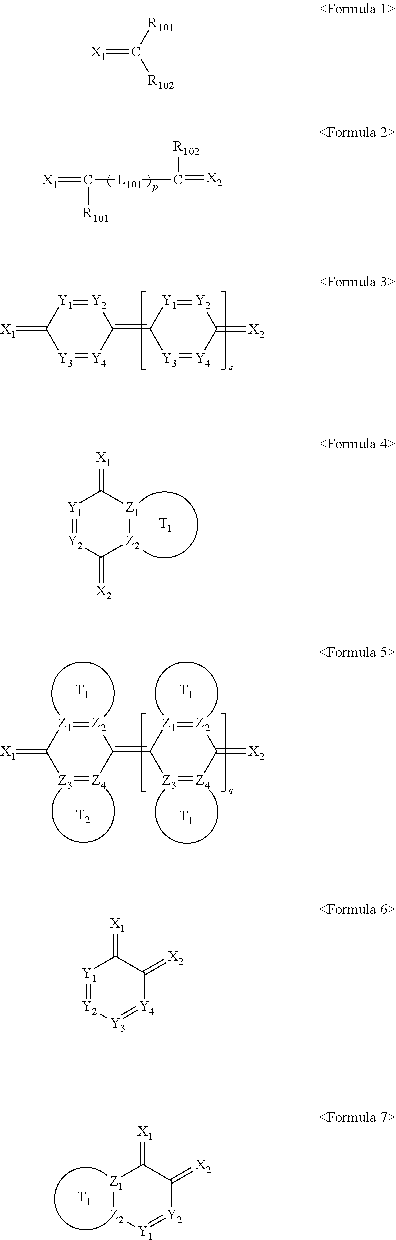

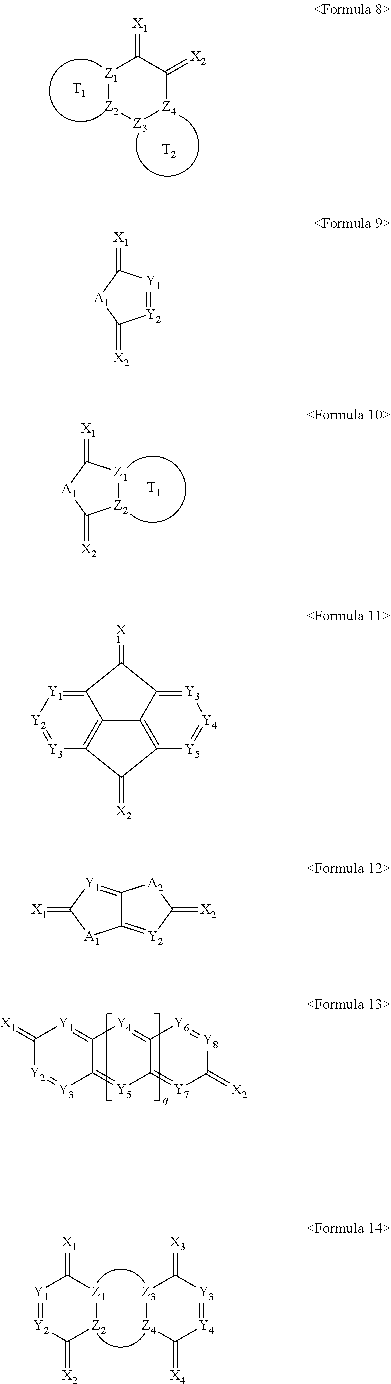

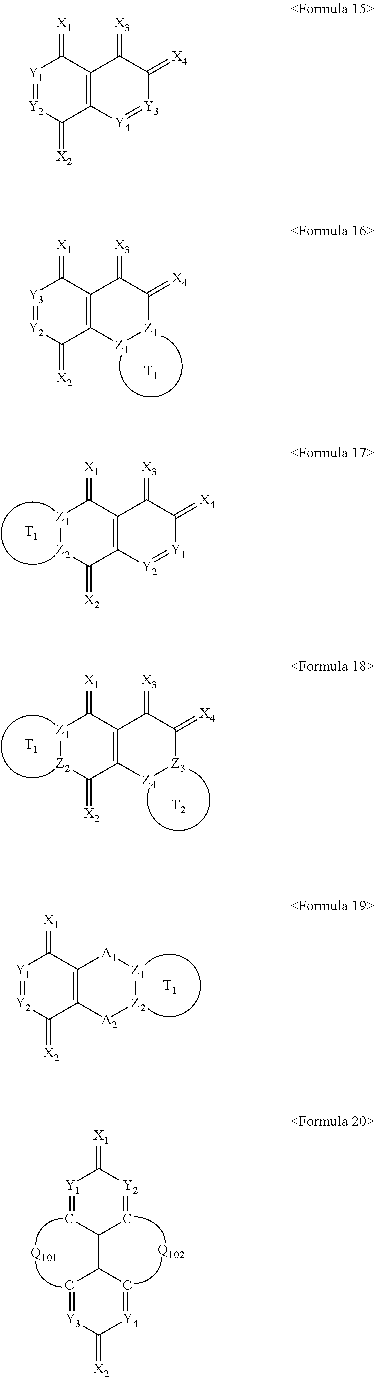

In Formulas 1 to 20:

X₁ to X₄ may be each independently selected from a compound of Formulas 30A to 30D.

Y₁ to Y₈ may be each independently selected from N and/or C(R₁₀₃).

Z₁ to Z₄ may be each independently C or N.

A₁ and A₂ may be each independently selected from —O—, —S—, —N(R₁₀₄), and/or —C(R₁₀₅)(R₁₀₆)—.

Q₁₀₁ and Q₁₀₂ may be each independently selected from:

a C₂-C₁₀ alkylene group; a C₂-C₁₀ alkenylene group; and/or

a C₂-C₁₀ alkylene group and/or a C₂-C₁₀ alkenylene group, each substituted with at least one substituent selected from a halogen atom, a cyano group, a hydroxyl group, a C₁-C₁₀ alkyl group, and/or a C₁-C₁₀ alkoxy group.

T₁ and T₂ may be each independently selected from:

a C₆-C₃₀ cyclic aromatic system;

a C₂-C₃₀ heterocyclic aromatic system; and/or

a C₆-C₃₀ cyclic aromatic system and/or a C₂-C₃₀ heterocyclic aromatic system, each substituted with at least one substituent selected from a halogen atom, a cyano group, a hydroxyl group, a C₁-C₁₀ alkyl group, and/or a C₁-C₁₀ alkoxy group.

p may be an integer from 1 to 10.

q may be an integer from 0 to 10.

R₁₀₁ to R₁₀₆ may be each independently selected from:

a hydrogen atom, a halogen atom, a cyano group, a hydroxyl group, a C₁-C₁₀ alkyl group and/or a C₁-C₁₀ alkoxy group;

a C₁-C₁₀ alkyl group and/or a C₁-C₁₀ alkoxy group, each substituted with at least one substituent selected from a hydrogen atom, a halogen atom, a cyano group, a hydroxyl group, a C₆-C₁₄ aryl group, and/or a C₂-C₁₄ heteroaryl group;

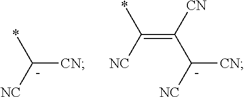 [SMILES: *[C-](C#N)C#N ; */C(C#N)=C(\C#N)[C-](C#N)C#N]

and/or

—N(R₁₀₇)(R₁₀₈), and R₁₀₇ and R₁₀₈ may be each independently selected from a hydrogen atom, a C₁-C₁₀ alkyl group, a phenyl group, and/or a biphenyl group.

L₁₀₁ may be selected from:

a C₆-C₁₄ arylene group;

a C₂-C₁₄ heteroarylene group; and/or

a C₂-C₁₀ alkenylene group, a C₆-C₁₄ arylene group, and/or a C₆-C₁₄ heteroarylene group, each substituted with at least one substituent selected from a halogen atom, a cyano group, a hydroxyl group, a C₁-C₁₀ alkyl group, and/or a C₁-C₁₀ alkoxy group.

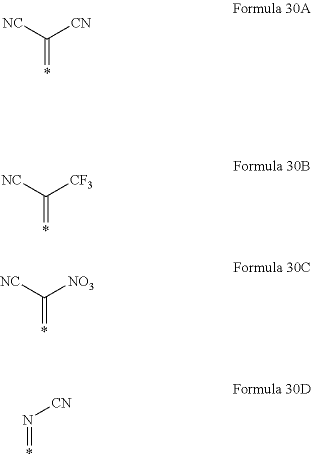

For example, in Formulas 1 to 20, X₁ to X₄ may be Formula 30A or 30D.

In an implementation, in C(R₁₀₃) that may be Y₁ to Y₈ in Formulae 1 to 20,

R₁₀₃ may be selected from a hydrogen atom, a halogen atom, a cyano group, a C₁-C₁₀ alkyl group and/or a C₁-C₁₀ alkoxy group;

a C₁-C₁₀ alkyl group and a C₁-C₁₀ alkoxy group, each substituted with at least one substituent selected from a halogen atom, a cyano group, a phenyl group, a naphthyl group, an anthryl group, a pyridinyl group, a thiophenyl group, and/or a benzothiophenyl group; and/or

—N(R₁₀₇)(R₁₀₈).

R₁₀₇ and R₁₀₈ may be each independently selected from a hydrogen atom, a C₁-C₁₀ alkyl group, a phenyl group, and/or a biphenyl group.

For example, R₁₀₃ may be selected from a hydrogen atom, —F, a cyano group, a methyl group, an ethyl group, a propyl group, an ethenyl group, a methoxy group, an ethoxy group, a propoxy group, a methyl group substituted with a phenyl group, a propyl group substituted with a phenyl group, and/or a bis(biphenyl)amino group, but is not limited thereto.

In Formulas 1 and 2, R₁₀₁ and R₁₀₂ may be each independently selected from a cyano group,

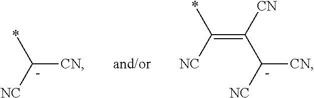 [SMILES: *[C-](C#N)C#N ; "and/or" ; */C(C#N)=C(\C#N)[C-](C#N)C#N]

but is not limited thereto.

In Formulas 1 to 20, A₁ and A₂ may be —S—, but is not limited thereto.

In Formula 20, Q₁₀₁ and Q₁₀₂ may be each independently selected from:

an ethylene group, a propylene group, an ethenylene group and/or a prophenylene group; and/or

an ethylene group, a propylene group, an ethenylene group, and/or a prophenylene group, each substituted with at least one substituent selected from a halogen atom, a cyano group, and/or a hydroxyl group.

For example, Q₁₀₁ and Q₁₀₂ may be each independently selected from an ethylene group and/or an ethenylene group; and/or an ethylene group and an ethenylene group, each substituted with one substituent selected from —F and/or a cyano group, but is not limited thereto.

In Formulas 1 to 20, T₁ and T₂ may be a C₆-C₃₀ cyclic aromatic system having Z₁ and Z₂, or Z₃ and Z₄, as constituent elements; a C₂-C₃₀ heterocyclic aromatic system; a C₆-C₃₀ cyclic aromatic system substituted with one substituent selected from a halogen atom, a cyano group, a hydroxyl group, a C₁-C₁₀ alkyl group, and a C₁-C₁₀ alkoxy group; or a C₂-C₃₀ heterocyclic aromatic system substituted with one substituent selected from a halogen atom, a cyano group, a hydroxyl group, a C₁-C₁₀ alkyl group, and/or a C₁-C₁₀ alkoxy group; wherein T₁ and T₂, as shown in the compounds of Formulas above, may be fused with a central backbone of the compounds of Formulas above and/or with more than one location in the compound of Formulas above.

The C₆-C₃₀ cyclic aromatic system may refer to a carbocyclic aromatic system having 6 to 30 carbon atoms including at least one aromatic ring. The term “system” used herein may be used to indicate that the C₆-C₃₀ cyclic aromatic system includes a polycyclic structure. When the C₆-C₃₀ cyclic aromatic system includes two or more aromatic rings, the two or more aromatic rings may be fused to each other. Meanwhile, the C₂-C₃₀ heterocyclic aromatic system may refer to a carbocyclic aromatic system having 2 to 30 carbon atoms including at least one heterocyclic aromatic ring consisting of at least one hetero atom selected from N, O, P, and S and carbon atoms as the remaining ring. Thus, when the C₂-C₃₀ heterocyclic aromatic system includes one or more aromatic rings in addition to the heterocyclic aromatic ring, and/or another heterocyclic aromatic ring in addition to the heterocyclic aromatic ring, the rings may be fused to each other.

The C₆-C₃₀ cyclic aromatic system may be, e.g., benzene, pentalene, indene, naphthalene, azulene, heptalene, indacene, acenaphthylene, fluorene, phenalene, phenanthrene, anthracene, fluoranthene, triphenylene, pyrene, chrysene, naphthacene, picene, perylene, pentaphene, hexacene, and the like, but is not limited thereto.

Examples of the C₆-C₃₀ cyclic aromatic system are pyrrole, pyrazole, imidazole, imidazoline, pyridine, pyrazine, pyrimidine, indole, purine, quinoline, phthalazine, indolizine, naphthyridine, quinazoline, cinnoline, indazole, carbazole, phenazine, phenanthridine, pyran, chromene, benzofuran, thiophene, benzothiophene, isothiazole, isoxazole, thiadiazole, oxadiazole, and the like, but are not limited thereto.

For example, in Formulas 1 to 20, T₁ and T₂ may be each independently selected from:

benzene, naphthalene, anthracene, thiophene, thiadiazole and/or oxadiazole; and/or

benzene, naphthalene, anthracene, thiophene, thiadiazole, and/or oxadiazole, each substituted with at least one substituent selected from a halogen atom, a cyano group, a C₁-C₁₀ alkyl group, and/or a C₁-C₁₀ alkoxy group, but is not limited thereto.

In Formulas 1 to 20, p may be 1, but is not limited thereto. Also, q may be 0, 1, or 2, but is not limited thereto. For example, when q in Formula 3 is 0, the compound of Formula 3 may be represented by Formula 3A that will be described later.

In Formula 2, L₁₀₁ may be selected from one of:

a C₆-C₁₄ arylene group;

a C₆-C₁₄ heteroarylene group;

a C₆-C₁₄ arylene group substituted with at least one substituent selected from a halogen atom, a cyano group, a hydroxyl group, a C₁-C₁₀ alkyl group, and/or a C₁-C₁₀ alkoxy group; and/or

a C₆-C₁₄ heteroarylene group substituted with at least one substituent selected from a C₂-C₁₀ alkenylene group, a halogen atom, a cyano group, a hydroxyl group, a C₁-C₁₀ alkyl group, and/or a C₁-C₁₀ alkoxy group.

For example, L₁₀₁ in Formula 2 above may be a thiophenylene group; a benzothiophenylene group; and a thiophenylene group and a benzothiophenylene group, each substituted with at least one substituent selected from a halogen atom, a cyano group, and/or a C₁-C₁₀ alkyl group; but is not limited thereto.

The cyano group-containing compound may be represented by one of the following Formulae 1A to 20B, but is not limited thereto.

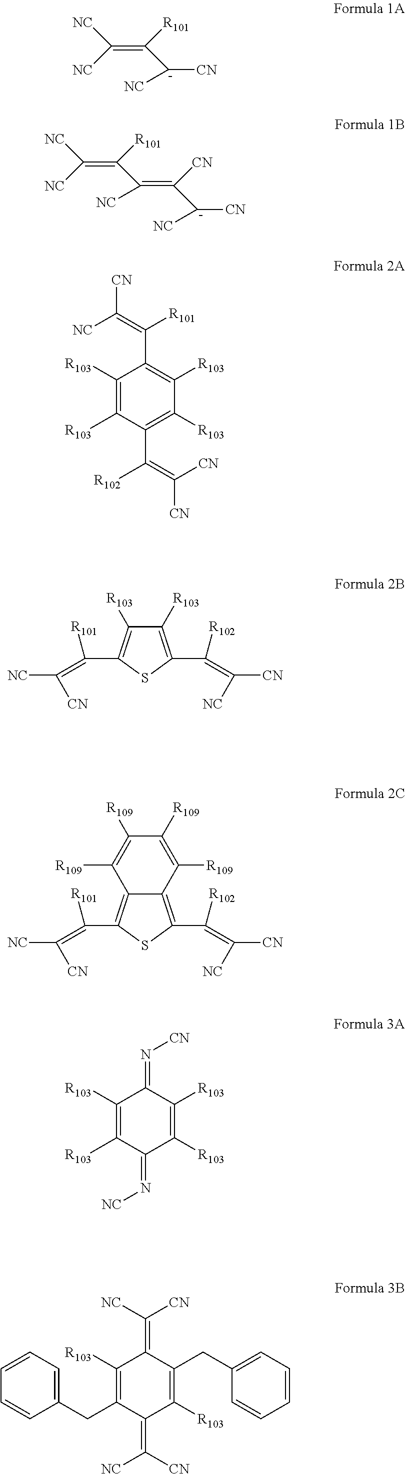

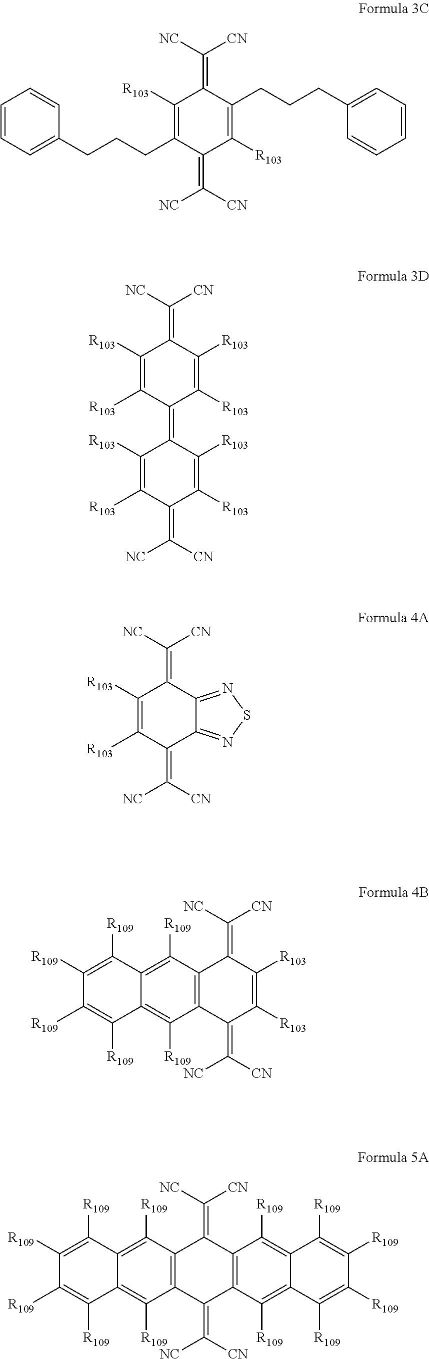

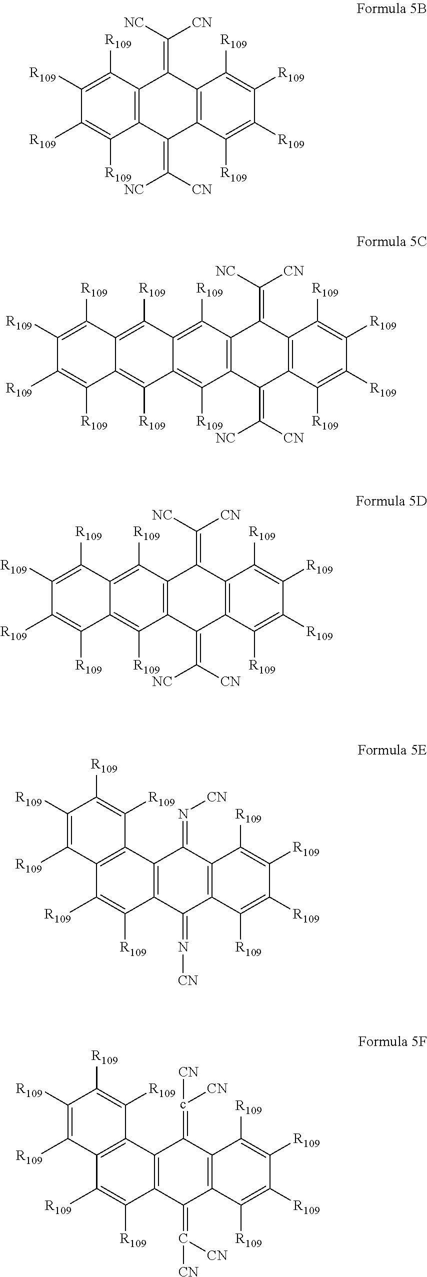

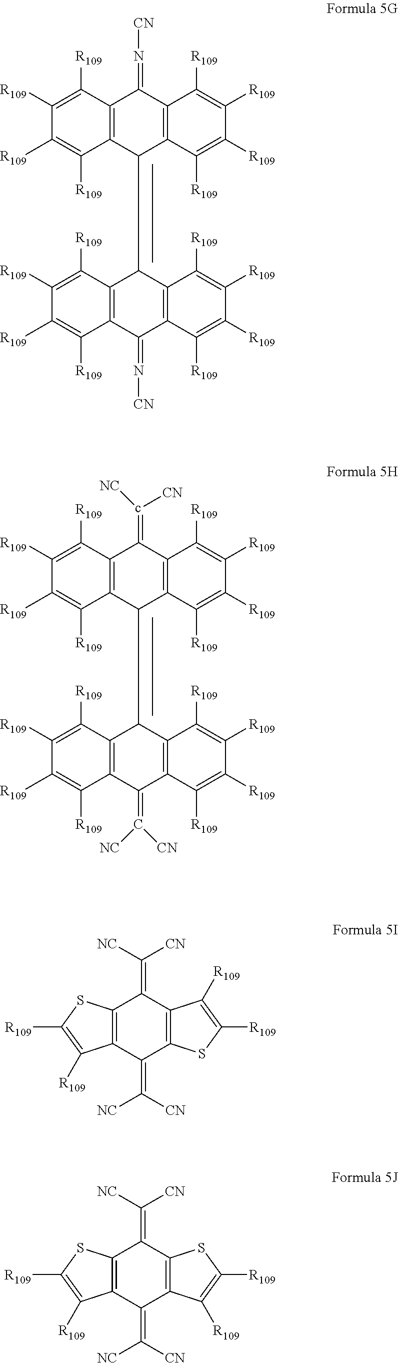

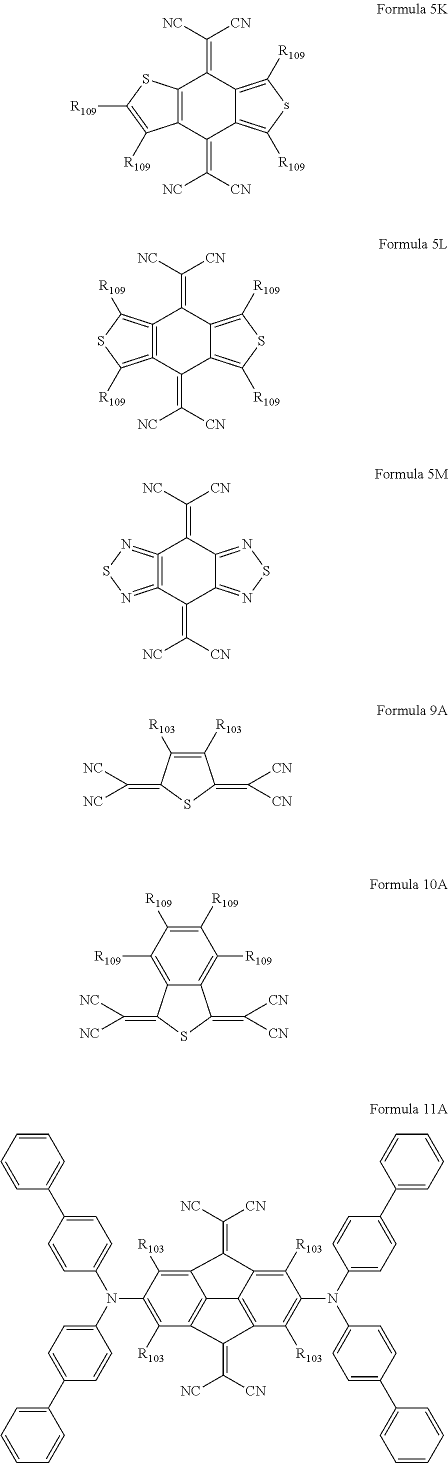

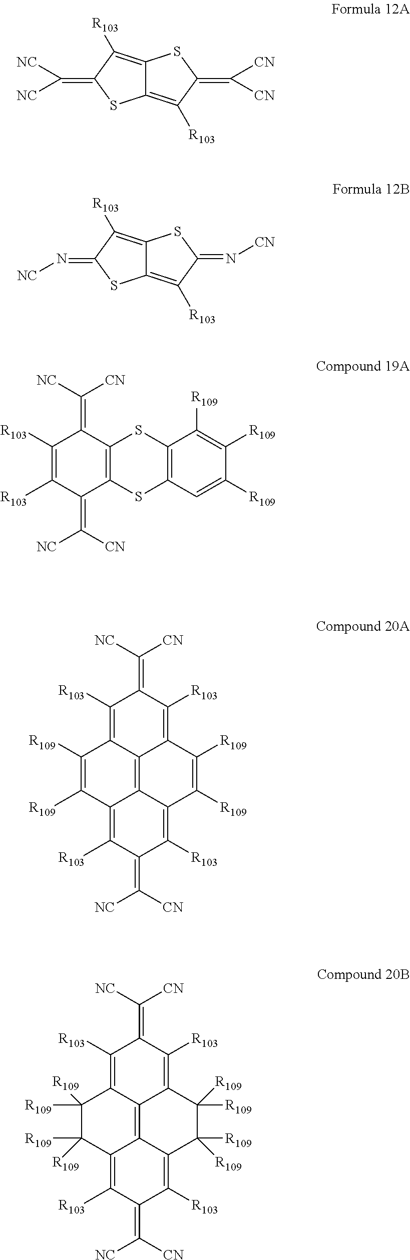

In Formulas 1A to 20B above, R₁₀₃ and R₁₀₉ may be each independently selected from a hydrogen atom, —F, a cyano group, a methyl group, an ethyl group, a propyl group, a methoxy group, an ethoxy group, and/or a propoxy group.

The cyano group-containing compound may be represented by Formula 20A or 20B above. In an implementation, R₁₀₃ and R₁₀₉ in Formula 20A or 20B may be both —F.

The compounds each included in the first interlayer 13-1 and the second interlayer 13-2 may be identical to each other. For example, the first interlayer 13-1 and the second interlayer 13-2 may both consist of Compound 40A.

In an implementation, the compounds each included in the first interlayer 13-1 and the second interlayer 13-2 may be different from each other. For example, the first interlayer 13-1 may consist of Compound 40A, and the second interlayer 13-2 may consist of Compound 40B.

A thickness of the first interlayer 13-1 and the second interlayer 13-2 may each be in a range from about 5 Å to about 100 Å, e.g., in a range from about 10 Å to about 50 Å. When the thickness of the first interlayer 13-1 and the second interlayer 13-2 is within these ranges, the OLED 10 may have good hole transporting ability without a substantial increase in driving voltage.

The thickness of the first interlayer 13-1 and the second interlayer 13-2 may be identical to each other. For example, the thickness in the first interlayer 13-1 and the second interlayer 13-2 may be both about 50 Å.

In an implementation, the thickness of the first interlayer 13-1 and the second interlayer 13-2 may be different from each other.

The first hole transport layer 14-1 and the second hole transport layer 14-2 may each independently include a known hole transporting compound. For example, the first hole transport layer 14-1 and the second hole transport layer 14-2 may include at least one compound selected from a first compound represented by Formula 41, below, and a second compound represented by Formula 42, below.

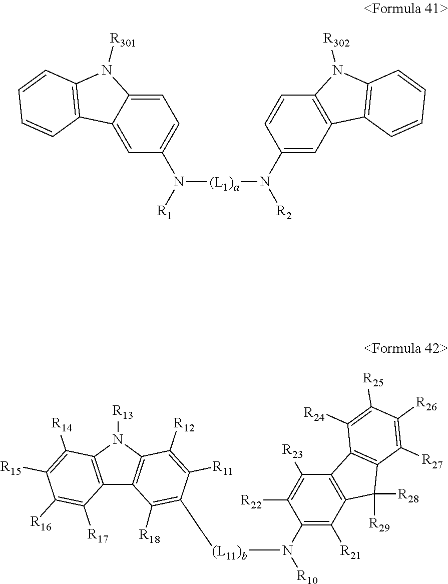

In Formulae 41 and 42, R₁₀ may be represented by —(Ar₁)ₙ—Ar₂;

R₁₆ may be represented by —(Ar₁₁)ₘ—Ar₁₂;

Ar₁, Ar₁₁, L₁, and L₁₁ may be each independently selected from a substituted or unsubstituted C₁-C₃₀ alkylene group, a substituted or unsubstituted C₂-C₃₀ alkenylene group, a substituted or unsubstituted C₆-C₃₀ arylene group, a substituted or unsubstituted C₂-C₃₀ heteroarylene group, and/or a group represented by —N(Q₁)-.

n, m, a, and b may be each independently an integer from 0 to 10.

R₁ to R₃, R₁₁ to R₁₅, R₁₇, R₁₈, R₂₁ to R₂₉, Ar₂, Ar₁₂, and Q₁ may be each independently selected from a hydrogen atom, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthio group, a substituted or unsubstituted C₆-C₃₀ aryl group, a C₄-C₃₀ heteroaryl group, and/or a group represented by —N(Q₂)(Q₃).

Q₂ and Q₃ may be each independently selected from a hydrogen atom, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthio group, a substituted or unsubstituted C₆-C₃₀ aryl group, and/or a C₄-C₃₀ heteroaryl group.

R₃₀₁ and R₃₀₂ may each independently be a substituted or unsubstituted C₆-C₃₀ aryl group.

Ar₁ in number of n in —(Ar₁)ₙ— may be identical to or different from each other, Ar₁₁ in number of m —(Ar₁₁)ₘ— may be identical to or different from each other. L₁ in number of a in -(L₁)ₐ- may be identical to or different each other, and L₁₁ in number of b in -(L₁₁)_{b}- may be identical to or different from each other.

Examples of Ar₁ and Ar₁₁ each in —(Ar₁)ₙAr₂— (e.g., R₁₀) and —(Ar₁₁)ₘ—Ar₁₂— are a substituted or unsubstituted C₁-C₁₀ alkylene group, a substituted or unsubstituted C₂-C₁₀ alkenylene group, a substituted or unsubstituted phenylene group, a substituted or unsubstituted pentalenylene, a substituted or unsubstituted indenylene, a substituted or unsubstituted naphthylene, a substituted or unsubstituted azulenylene, a substituted or unsubstituted heptalenylene, a substituted or unsubstituted indacenylene, a substituted or unsubstituted acenaphthylene, a substituted or unsubstituted fluorenylene, a substituted or unsubstituted phenalenylene, a substituted or unsubstituted phenanthrenylene, a substituted or unsubstituted anthracenylene, a substituted or unsubstituted fluoranthenylene, a substituted or unsubstituted triphenylenylene, a substituted or unsubstituted pyrenylenylene, a substituted or unsubstituted chrysenylene, a substituted or unsubstituted naphthacenylene, a substituted or unsubstituted picenylene, a substituted or unsubstituted perylenylene, a substituted or unsubstituted pentaphenylene, a substituted or unsubstituted hexacenylene, a substituted or unsubstituted pyrrolylene, a substituted or unsubstituted pyrazolylene, a substituted or unsubstituted imidazolylene, a substituted or unsubstituted imidazolinylene, a substituted or unsubstituted imidazopyridinylene, a substituted or unsubstituted imidazopyrimidinylene, a substituted or unsubstituted pyridinylene, a substituted or unsubstituted pyrazinylene, a substituted or unsubstituted pyrimidinylene, a substituted or unsubstituted indolylene, a substituted or unsubstituted purinylene, a substituted or unsubstituted quinolinylene, a substituted or unsubstituted phthalazinylene, a substituted or unsubstituted indolizinylene, a substituted or unsubstituted naphthyridinylene, a substituted or unsubstituted quinazolinylene, a substituted or unsubstituted cinnolinylene, a substituted or unsubstituted indazolylene, a substituted or unsubstituted carbazolylene, a substituted or unsubstituted phenazinylene, a substituted or unsubstituted phenanthridinylene, a substituted or unsubstituted pyranylene, a substituted or unsubstituted chromenylene, a substituted or unsubstituted benzofuranylene, a substituted or unsubstituted thiophenylene, a substituted or unsubstituted benzothiophenylene, a substituted or unsubstituted isothiazolylene, a substituted or unsubstituted benzoimidazolylene, a substituted or unsubstituted isoxazolylene, a substituted or unsubstituted triazinylene, and/or a group represented by —N(Q₁)-, but are not limited thereto. Here, Q₁ may be, e.g., selected from a hydrogen atom, a halogen atom, a hydroxyl group, a cyano group, a substituted or unsubstituted C₁-C₁₀ alkyl group, a substituted or unsubstituted C₂-C₁₀ alkenyl group, a substituted or unsubstituted C₂-C₁₀ alkynyl group, a substituted or unsubstituted C₁-C₁₀ alkoxy group, a substituted or unsubstituted C₁-C₁₀ alkylthio group, a substituted or unsubstituted C₆-C₁₄ aryl group, a C₂-C₁₄ heteroaryl group, and/or a group represented by —N(Q₂)(Q₃), but is not limited thereto.

In an implementation, Ar₁ and Ar₁₁ may be each independently selected from:

a C₁-C₁₀ alkylene group, a phenylene group, a naphthylene group, an anthrylene group, a fluorenylene group, a carbazolylene group, a pyrazolylene group, a pyridinylene group, a triazinylene group and/or —N(Q₁)-; and/or

a C₁-C₁₀ alkylene group, a phenylene group, a naphthylene group, an anthrylene group, a fluorenylene group, a carbazolylene group, a pyrazolylene group, a pyridinylene group, and/or a triazinylene group, each substituted with at least one substituent selected from a halogen atom, a cyano group, a hydroxyl group, a C₁-C₁₀ alkyl group, a C₁-C₁₀ alkoxy group, a phenyl group, a naphthyl group, and/or an anthryl group, but is not limited thereto. In an implementation, Q₁ may be selected from a hydrogen atom; a C₁-C₁₀ alkyl group; a phenyl group; a naphthyl group; a carbazolylene group; a fluorenyl group; a pyrenyl group; a C₁-C₁₀ alkyl group, a C₁-C₁₀ alkoxy group, a phenyl group, a naphthyl group, a carbazolylene group, a fluorenyl group, and/or a pyrenyl group, each substituted with at least one substituent selected from a halogen atom, a cyano group, a hydroxyl group, a C₁-C₁₀ alkyl group, a C₁-C₁₀ alkoxy group, a phenyl group, a naphthyl group, and/or an anthryl group; and/or —N(Q₂)(Q₃), but is not limited thereto. In an implementation, Q₂ and Q₃ may be selected from a methyl group, a phenyl group, a naphthyl group, and/or an anthryl group.

R₃₀₁ and R₃₀₂ may be each independently selected from:

a phenyl group and/or a naphthyl group; and/or

a phenyl group and/or a naphthyl group, each substituted with at least one substituent selected from a deuterium atom, a halogen atom, a cyano group, and/or a C₁-C₁₀ alkyl group, but is not limited thereto.

Are and Ar₁₂ each in —(Ar₁)ₙ—Ar₂— and —(Ar₁₁)ₘ—Ar₁₂— may be defined as above in conjunction with Q₁ above, and thus detailed descriptions thereof may not be provided here.

In —(Ar₁)ₙ—Ar₂— and —(Ar₁₁)ₘ—Ar₁₂—, n and m may be each independently an integer from 0 to 10. For example, n and m may be each independently 0, 1, 2, 3, 4, or 5, but is not limited thereto.

Ar₁ in number of n (—(Ar₁)ₙ—) in —(Ar₁)ₙAr₂— may be identical to or different from each other. For example, when n is 2, two Ar₁s in —(Ar₁)ₙ— may be both a phenylene groups, or one Ar₁ may be —N(Q₁)- and the other Ar₁ may be a phenylene group so as to have wide variations. The —(Ar₁₁)ₘ—Ar₁₂— may be defined as above.

R₁ to R₃, R₁₁ to R₁₅, R₁₇, R₁₈, and R₂₁ to R₂₉ in Formulas 41 and 42 may be defined as described above in conjunction with Q₁, and thus detailed descriptions thereof may not be provided here.

For example, R₁₃ may be a phenyl group, a naphthyl group, or an anthryl group, but is not limited thereto.

For example, R₂₈ and R₂₉ may be each independently selected from a hydrogen atom, a methyl group, an ethyl group, a methoxy group, an ethoxy group, a phenyl group, a naphthyl group, and/or an anthryl group, but is not limited thereto.

L₁ and L₂ in Formulas 41 and 42 may be defined as Ar₁ and Ar₁₁ above.

For example, L₁ and L₂ may be each independently selected from a phenylene group, a carbazolylene group, or a phenylcarbazolylene group, but is not limited thereto.

In Formulae 41 and 42, a and b may be each independently an integer from 1 to 10. For example, a and b may be each independently 0, 1, 2, or 3, but is not limited thereto.

In an implementation, in Formula 42,

Ar₁ in —(Ar₁)ₙ—Ar₂— (e.g., R₁₀) and Ar₁₁ in —(Ar₁₁)ₘ—Ar₁₂— (that is, R₁₆) may be each independently selected from a phenylene group, a carbazolylene group, a fluorenylene group, a methyl fluorenylene group, a pyrazolylene group, a phenyl pyrazolylene group, —N(Q₁)- (wherein, Q₁ may be a hydrogen atom, a phenyl group, a fluorenyl group, a dimethyl fluorenyl group, a diphenyl fluorenyl group, a carbazolylene group, a phenyl carbazolylene group, or the like), a diphenyl fluorenylene group, a triazinylene group, a methyl triazinylene group, a phenyl triazinylene group, a tetrafluoro phenylene group, an ethylen group, and/or a methyl phenylene group, n amd m may be each independently 0, 1, 2, 3, 4, 5, or 6, and Ar₂ and Ar₁₂ may be selected from a hydrogen atom, a cyano group, a fluorine group, a phenyl group, a cyanophenyl group, a naphthyl group, an anthryl group, a methyl group, a pyridinyl group, a carbazolylene group, a phenyl carbazolylene group, a fluorenyl group, a dimethyl fluorenyl group, and/or a diphenyl fluorenyl group;

R₁₁, R₁₂, R₁₄, R₁₅, R₁₇, R₁₈, and R₂₁ to R₂₇ may each be a hydrogen atom;

R₁₃ may be selected from a phenyl group, a naphthyl group, and/or an anthryl group;

R₂₈ and R₂₉ may be each independently selected from a hydrogen atom, a methyl group, an ethyl group, a methoxy group, an ethoxy group, a phenyl group, a naphthyl group, and/or an anthryl group;

L₁₁ may be a phenylene group; and

b may be 0 or 1.

In an implementation, the first compound represented by Formula 41 may be one of Compounds 301 to 308 below, and the second compound represented by Formula 42 may be one of Compounds 309 to 320 below, but are not limited thereto.

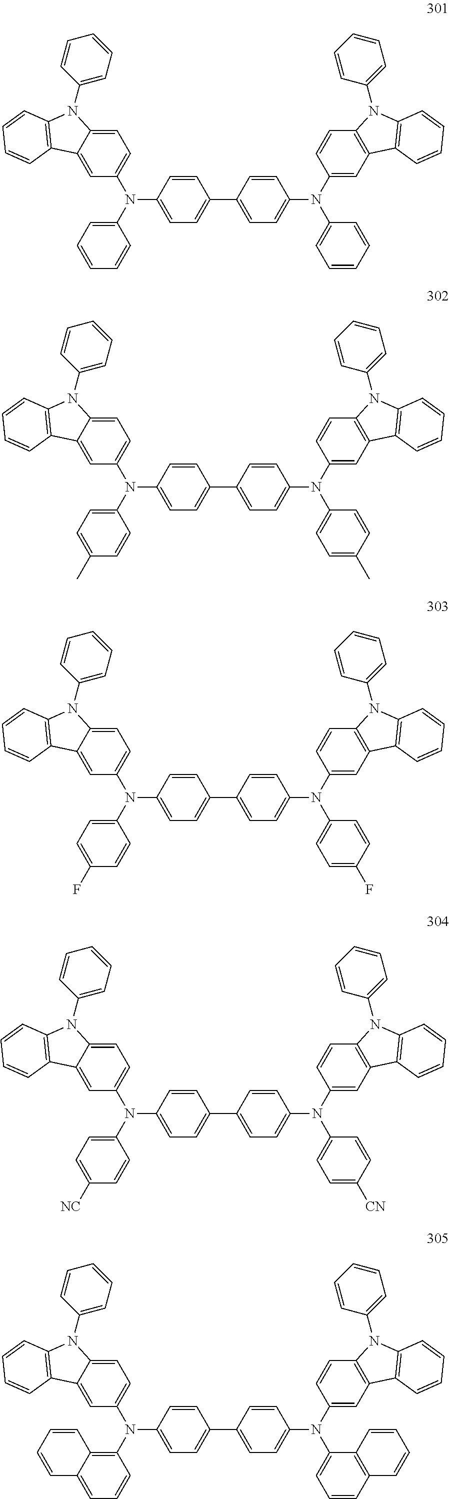

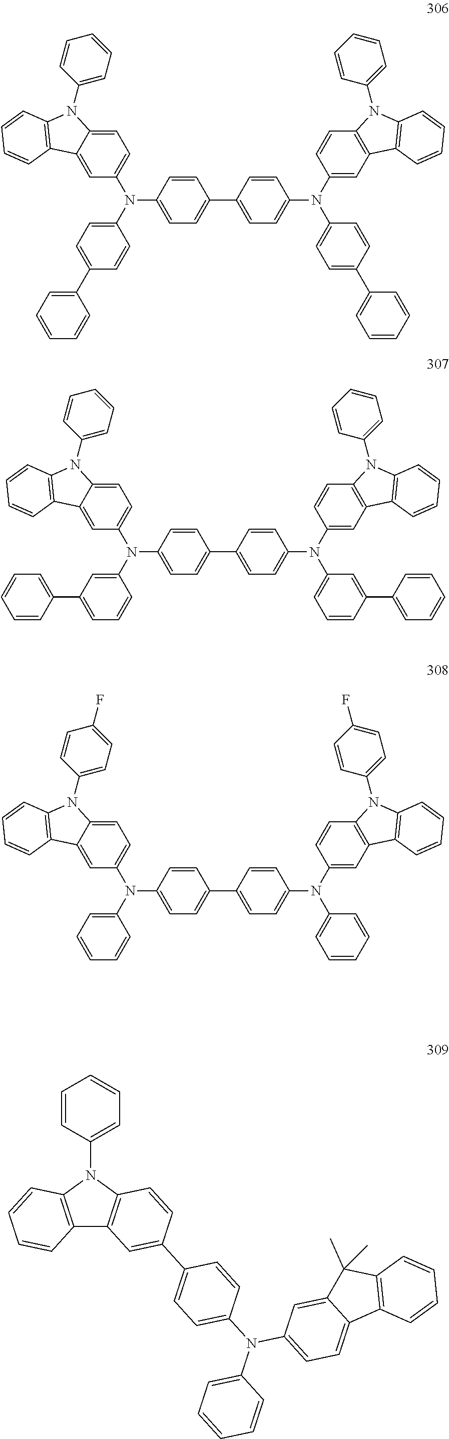 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; CC1(C)c2ccccc2-c2ccc(N(c3ccccc3)c3ccc(-c4ccc5c(c4)c4ccccc4n5-c4ccccc4)cc3)cc21]

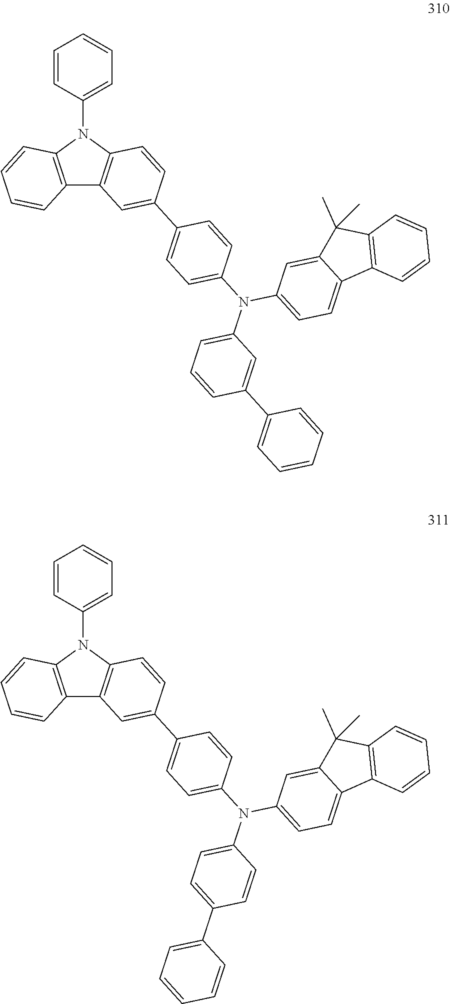 [SMILES: CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

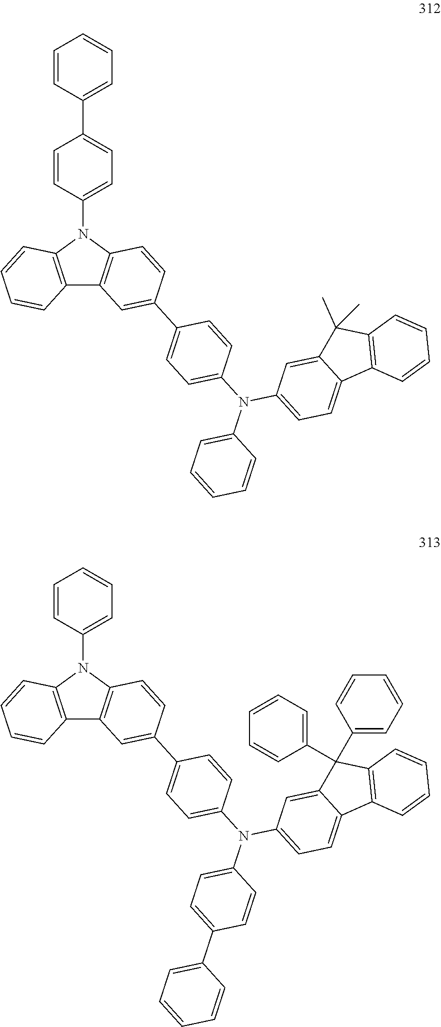 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

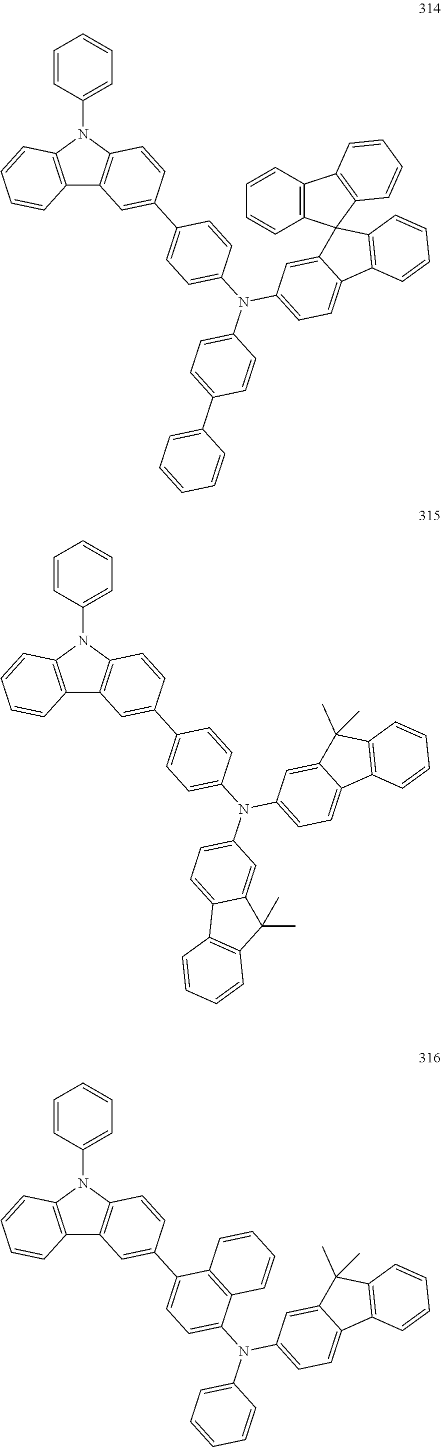 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

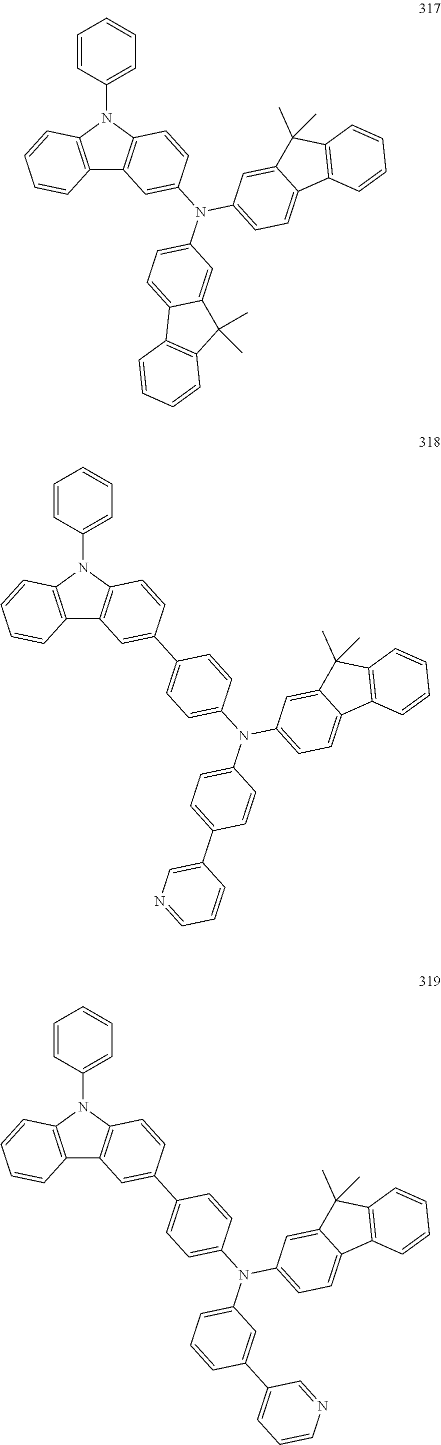 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

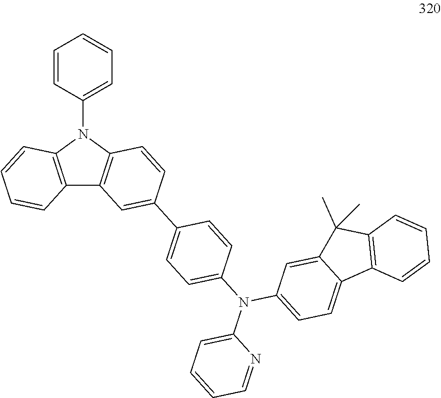 [SMILES: CC1(C)c2ccccc2-c2ccc(N(c3ccc(-c4ccc5c(c4)c4ccccc4n5-c4ccccc4)cc3)c3ccccn3)cc21]

The first HTL 14-1 may include the first compound of Formula 41, and the second HTL 14-2 may include the second compound of Formula 42.

For example, the first HTL 14-1 may include any one of Compounds 301 to 308, and the second HTL 14-2 may include any one of Compounds 309 to 320, but are not limited thereto.

The thickness of the first HTL 14-1 and the second HTL 14-2 may be each in a range from about 10 Å to about 2,000 Å, e.g., in a range from about 100 Å to 1,000 Å. When the thickness of the first HTL 14-1 and the second HTL are within these ranges, the OLED 10 may have good hole transporting ability without increasing a substantial increase in driving voltage.

The materials included in the first HTL 14-1 and the second HTL 14-2 may not be included in the first interlayer 13-1 and the second interlayer 13-2. Likewise, the materials included in the first interlayer 13-1 and the second interlayer 13-2 may not be included in the first HTL 14-1 and the second HTL 14-2.

The first interlayer 13-1, the first HTL 14-1, the second interlayer 13-2, and the second HTL 14-2 may be formed on the first electrode 12 by any of a variety of methods, including vacuum deposition, spin coating, casting, and Langmuir-Blodgett (LB) deposition.

When the first interlayer 13-1, the first HTL 14-1, the second interlayer 13-2, and the second HTL 14-2 are formed using vacuum deposition, the deposition conditions may vary depending on the compound that is used to form the above-mentioned layers, and the desired structure and thermal properties of the HIL to be formed. For example, the vacuum deposition may be performed at a temperature of about 100° C. to about 500° C., at a pressure of about 10⁻⁸ torr to about 10⁻³ torr, and at a deposition rate of about 0.01 Å/sec to about 100 Å/sec, but is not limited thereto.

When the first interlayer 13-1, the first HTL 14-1, the second interlayer 13-2, and the second HTL 14-2 are formed using spin coating, the coating conditions may vary depending on the compound that is used to form the above-mentioned layers, and the desired structure and thermal properties of the HIL to be formed. For example, the spin coating may be performed at a coating rate of about 2,000 rpm to about 5,000 rpm, and at a temperature of about 80° C. to about 200° C. to remove a solvent after coating, but is not limited thereto.

The above-described first interlayer 13-1, the first HTL 14-1, the second interlayer 13-2, and the second HTL 14-2 are sequentially deposited between the first electrode 12 and the EML 15, and thus the first interlayer 13-1 may enhance characteristics of the hole injection injected from the first electrode 12 to the first HTL 14-1 while the second interlayer 13-2 may enhance characteristics of the hole transport transporting from the first HTL 14-1 to the second HTL 14-2. Therefore, the OLED 10 may improve characteristics such as driving voltage, luminescent efficiency, brightness, lifetime, and the like.

The EML 15 may include a host and a dopant.

Examples of the host are Alq₃, 4,4′-N,N′-dicarbazole-biphenyl (CBP), poly(n-vinylcarbazole) (PVK), 9,10-di(naphthalene-2-yl)anthracene (ADN), TCTA, 1,3,5-tris(N-phenylbenzimidazole-2-yl)benzene (TPBI), 3-tert-butyl-9,10-di-2-naphthylanthracene (TBADN), E3, distyrylarylene (DSA), dmCBP (see a formula below), and Compounds 501 to 509 below, but are not limited thereto.

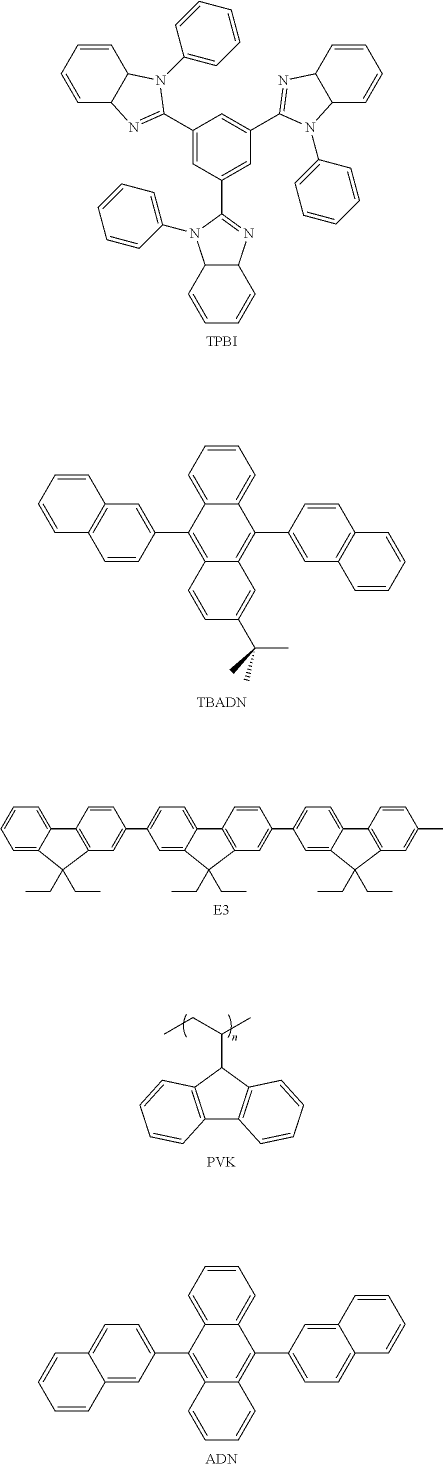

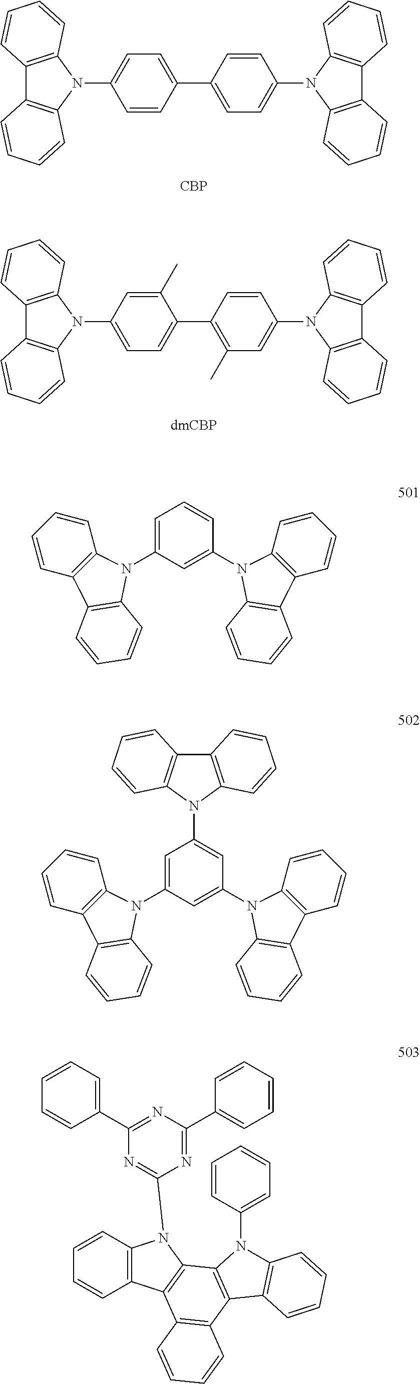

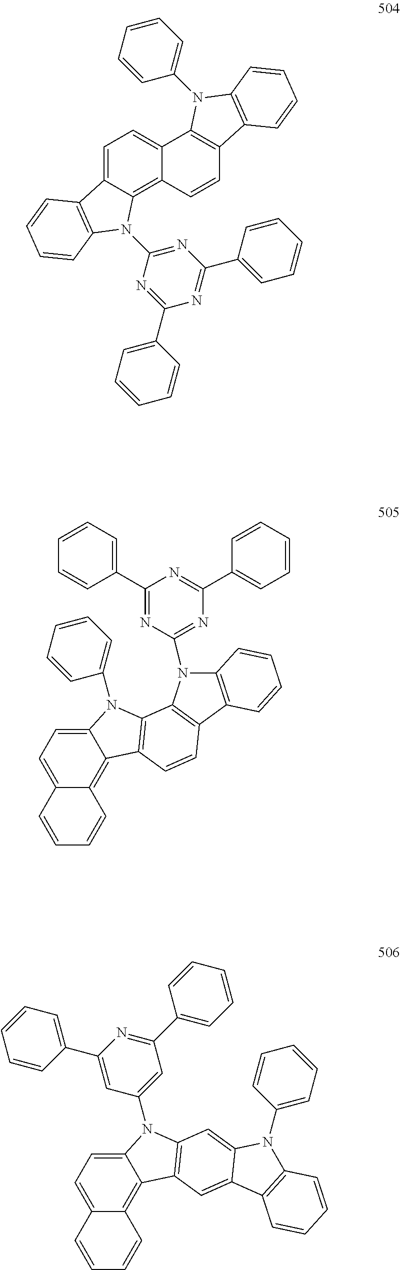 [SMILES: c1ccc(-c2nc(-c3ccccc3)nc(-n3c4ccccc4c4ccc5c(ccc6c7ccccc7n(-c7ccccc7)c65)c43)n2)cc1 ; c1ccc(-c2nc(-c3ccccc3)nc(-n3c4ccccc4c4ccc5c6c7ccccc7ccc6n(-c6ccccc6)c5c43)n2)cc1 ; c1ccc(-c2cc(-n3c4cc5c(cc4c4c6ccccc6ccc43)c3ccccc3n5-c3ccccc3)cc(-c3ccccc3)n2)cc1]

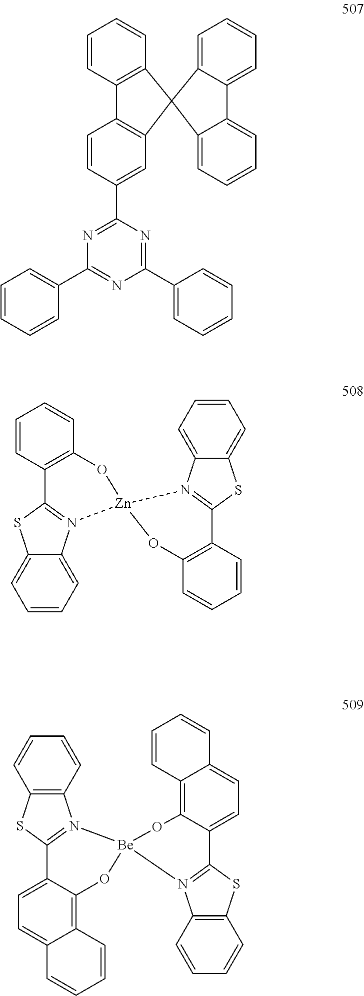

In an implementation, an anthracene-based compound represented by Formula 400, below, may be used as the host.

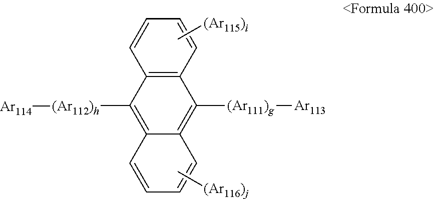

In Formula 400, Ar₁₁₁ and Ar₁₁₂ may be each independently a substituted or unsubstituted C₆-C₆₀ arylene group;

Ar₁₁₃ to Ar₁₁₆ may be each independently a substituted or unsubstituted C₁-C₁₀ alkyl group or a substituted or unsubstituted C₆-C₆₀ aryl group; and

g, h, I, and j may be each independently an integer from 0 to 4.

In an implementation, Ar₁₁₁ and Ar₁₁₂ in Formula 400 may be each independently selected from:

a phenylene group, a naphthylene group, a phenanthrenylene group, and/or a pyrenylene group; and/or

a phenylene group, a naphthylene group, a phenanthrenylene group, a fluorenyl group, and/or a pyrenylene group, each substituted with at least one of a phenyl group, a naphthyl group, and/or an anthryl group, but is not limited thereto:

In Formula 400, g, h, I, and j may be each independently 0, 1, or 2.

In an implementation, Ar₁₁₃ to Ar₁₁₆ in Formula 400 may be each independently selected from:

a C₁-C₁₀ alkyl group substituted with at least one of a phenyl group, a naphthyl group, and/or an anthryl group;

a phenyl group, a naphthyl group, an anthryl group, a pyrenyl group, a phenanthrenylene group and/or a fluorenyl group;

a phenyl group, a naphthyl group, an anthryl group, a pyrenyl group, a phenanthrenylene group, and/or a fluorenyl group, each substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereto, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthryl group, a pyrenyl group, a phenanthrenylene group, and/or a fluorenyl group; and/or

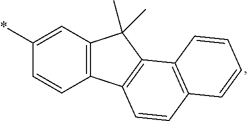 [SMILES: *c1ccc2c(c1)C(C)(C)c1c-2ccc2ccccc12]

but is not limited thereto.

For example, the anthracene-based compound of Formula 400, above, may be one of the compounds represented by the following Formulae, but is not limited thereto.

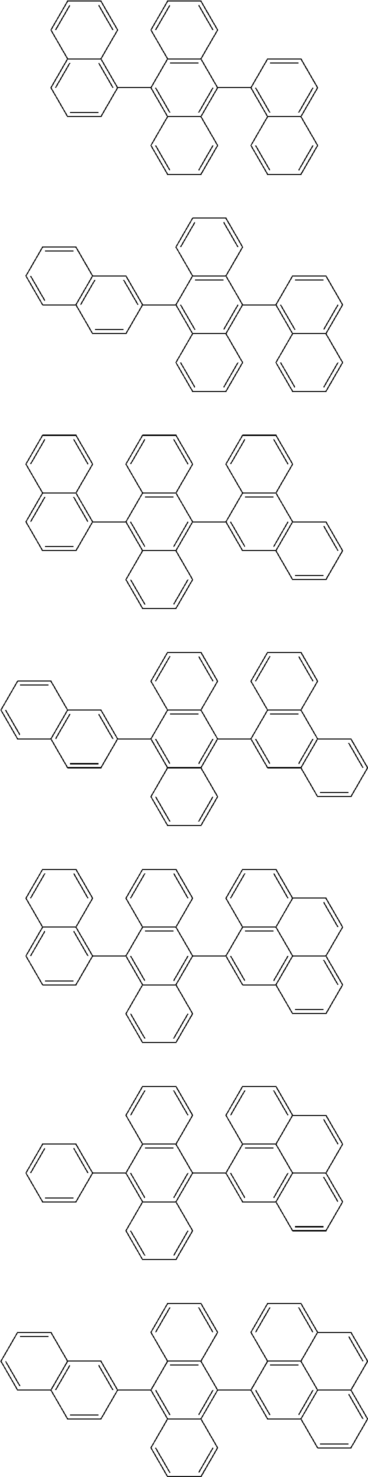

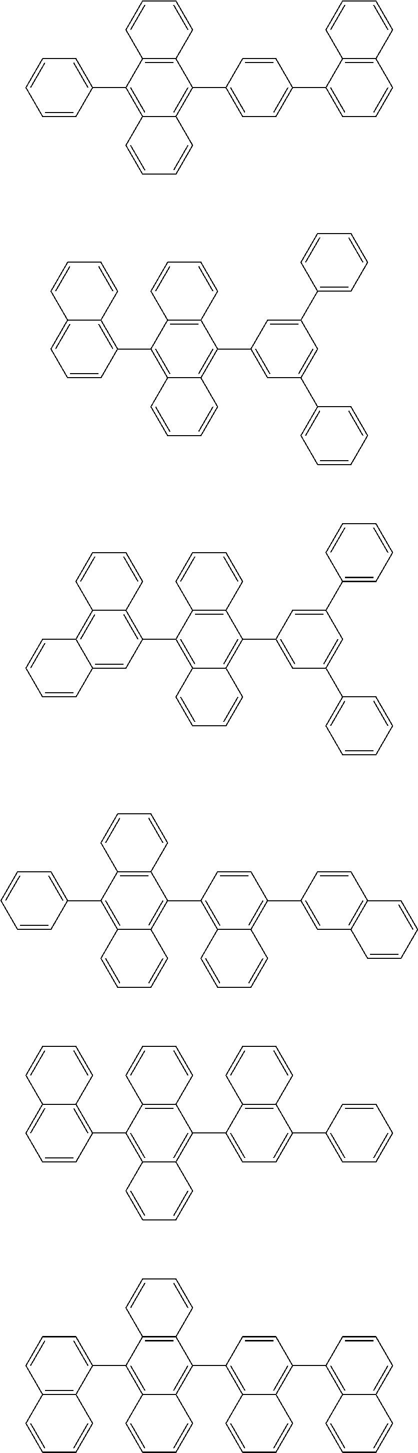

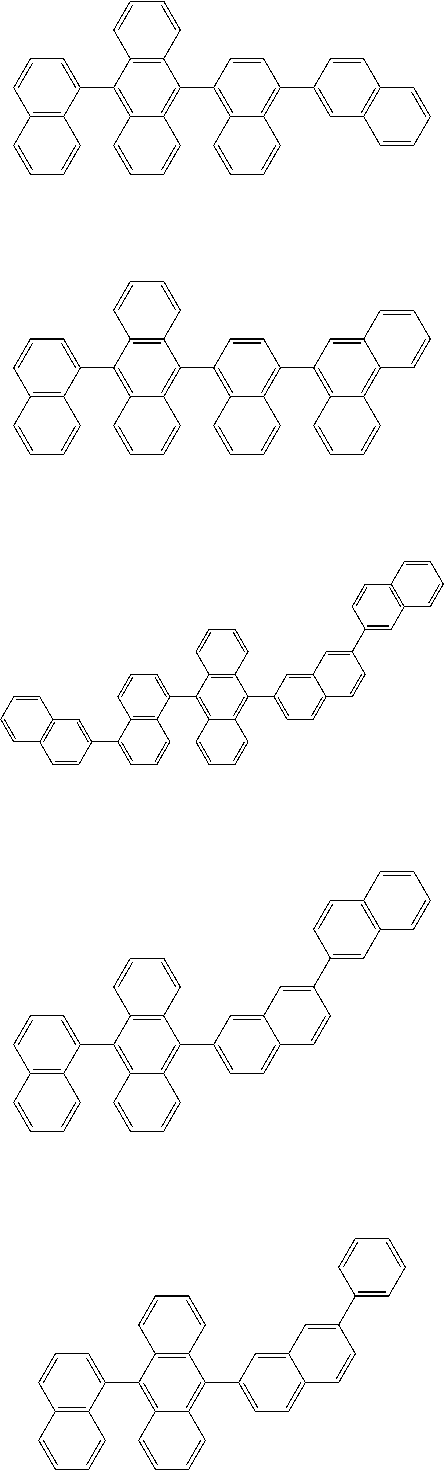

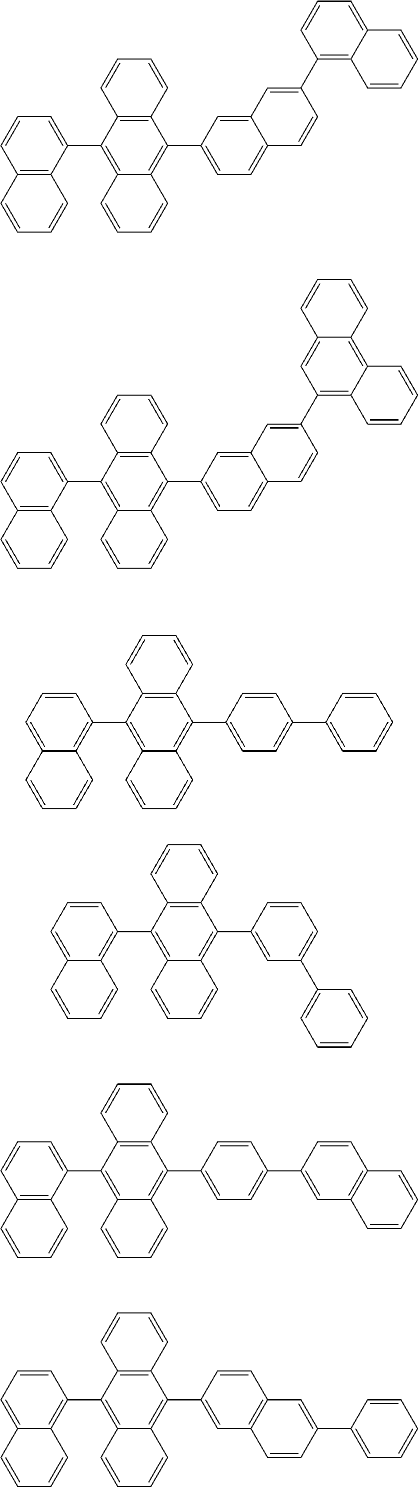

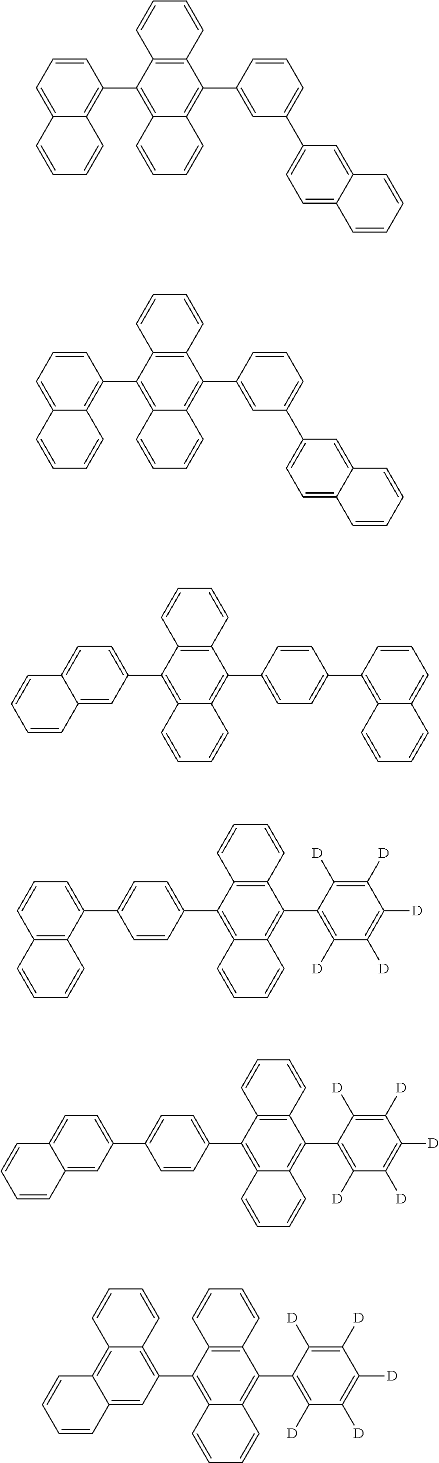

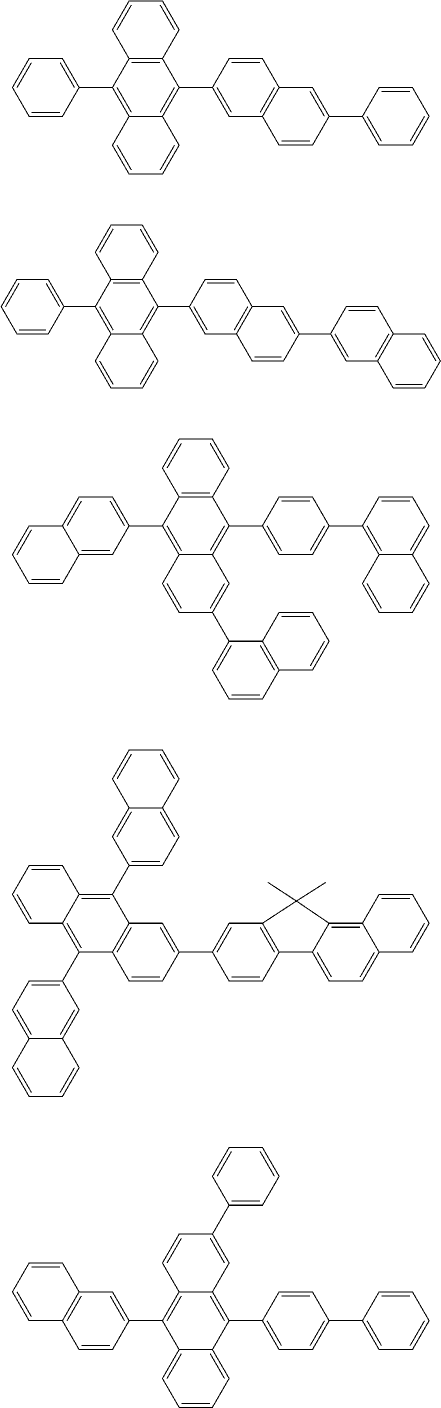

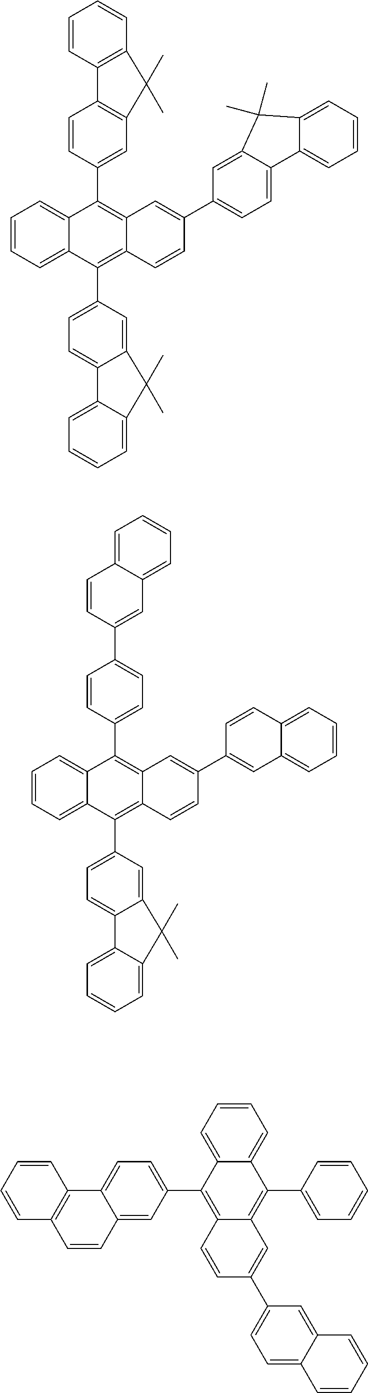

In an implementation, an anthracene-based compound represented by Formula 401 below may be used as the host.

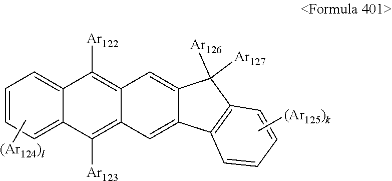

In Formula 401, Ar₁₂₂ to Ar₁₂₅ may be defined as described above in conjunction with Ar₁₁₃ in Formula 400, and thus detailed descriptions thereof may not be provided here.

Ar₁₂₆ and Ar₁₂₇ in Formula 401 above may be each independently a C₁-C₁₀ alkyl group (i.e., a methyl group, an ethyl group, or a propyl group).

In Formula 401, k and l may be each independently an integer from 0 to 4. For example, k and I may be 0, 1, or 2.

In an implementation, the anthracene-based compound of Formula 401 above may include one of the compounds represented by the following formulae, but is not limited thereto.

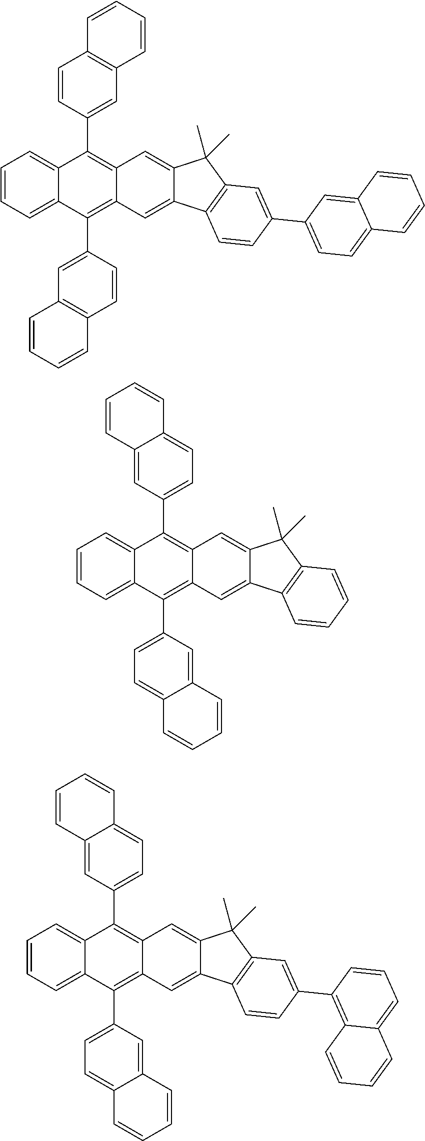

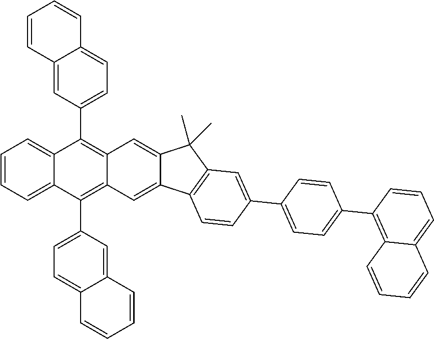 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

When the OLED is a full color OLED, the EML may be patterned into a red EML, a green EML, and a blue EML. The EML may have wide variations to emit light. For example, due to a stack structure including a red EML, a green EML, and/or a blue EML, the EML may emit white light.

A dopant included in the EML may be a suitable dopant.

At least one of the red EML, the green EML, and the blue EML may include one of the dopants, below. (ppy=phenylpyridine)

Examples of the blue EML are compounds represented by the following formulae, but are not limited thereto.

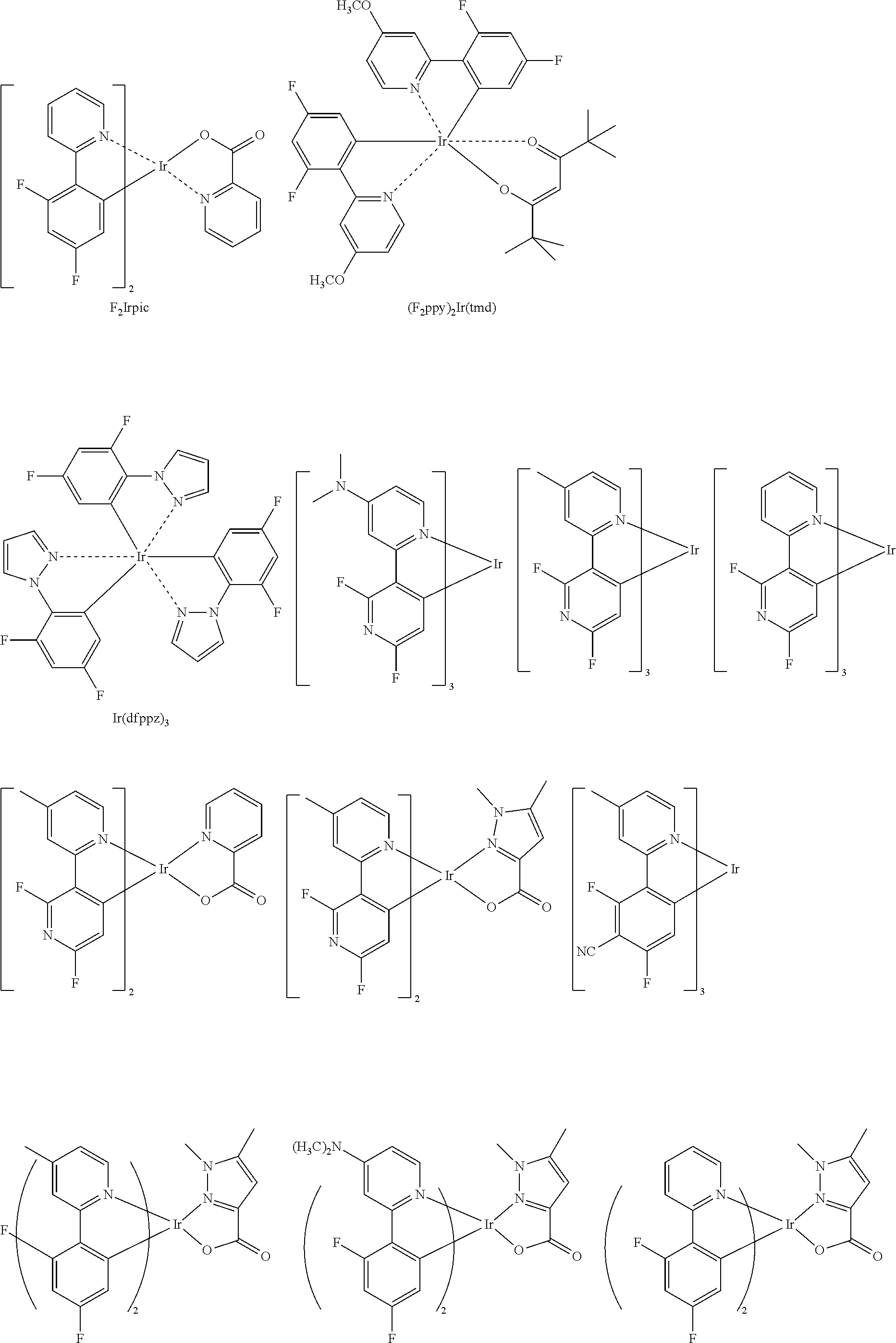

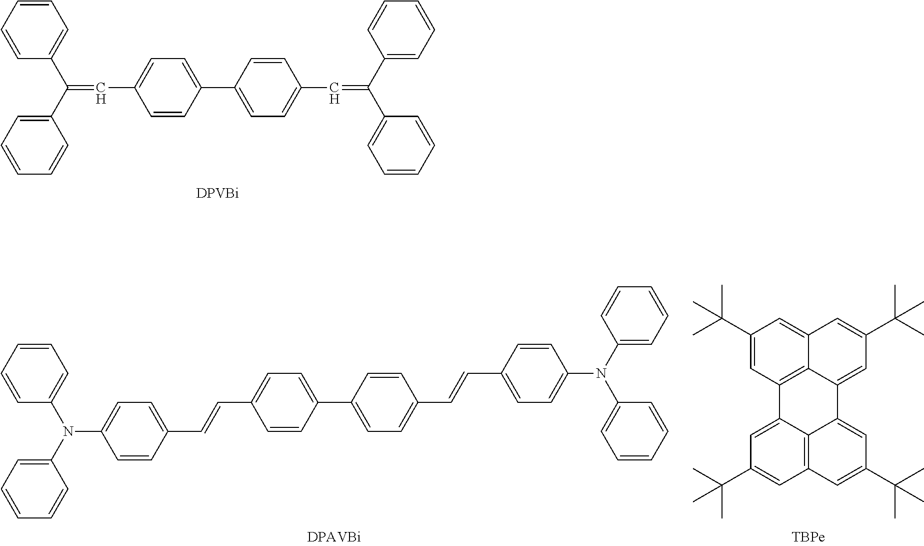

Examples of the red EML are compounds represented by the following formulas, but are not limited thereto. Also, as the red EML, DCM or DCJTB, which will be described below, may be used.

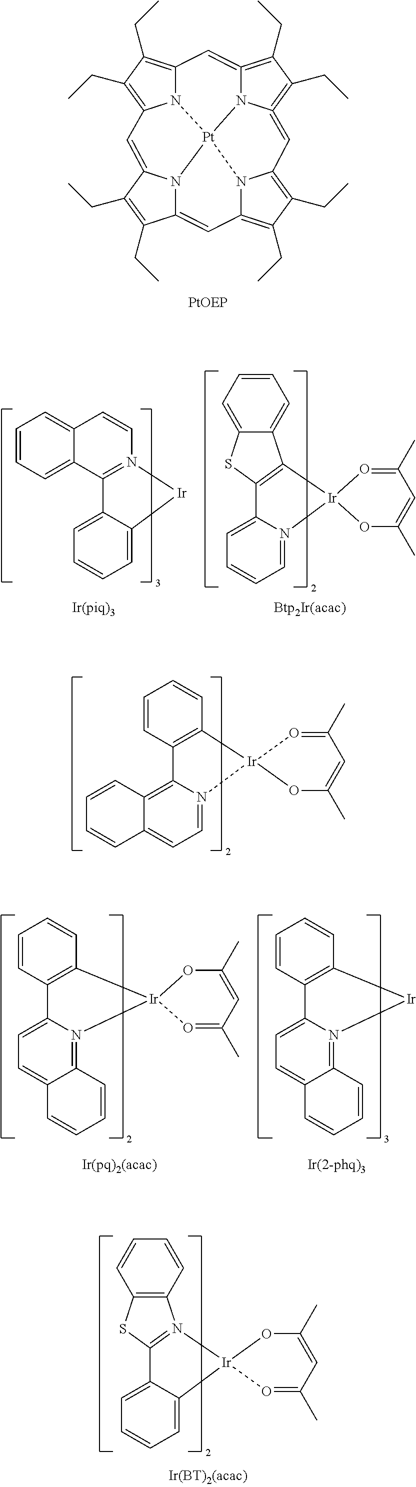

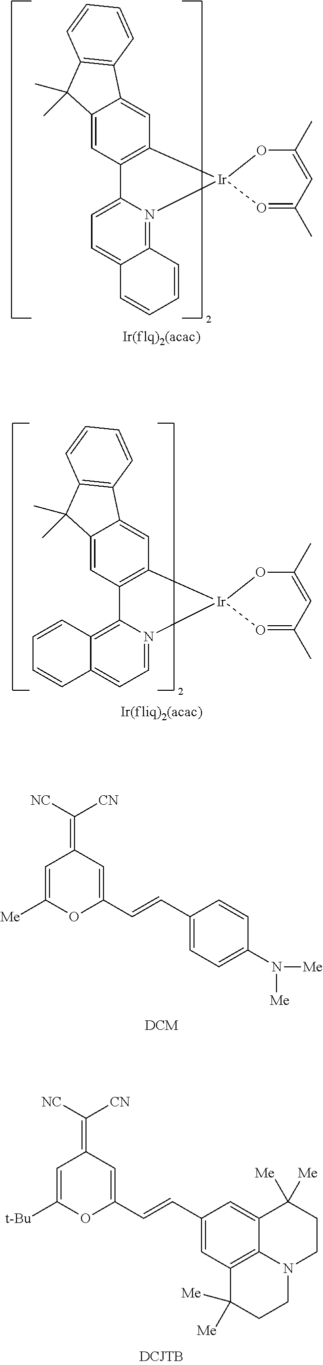

Examples of the green EML are compounds represented by the following formulas, but are not limited thereto. Also, as the green EML, C545T may be used.

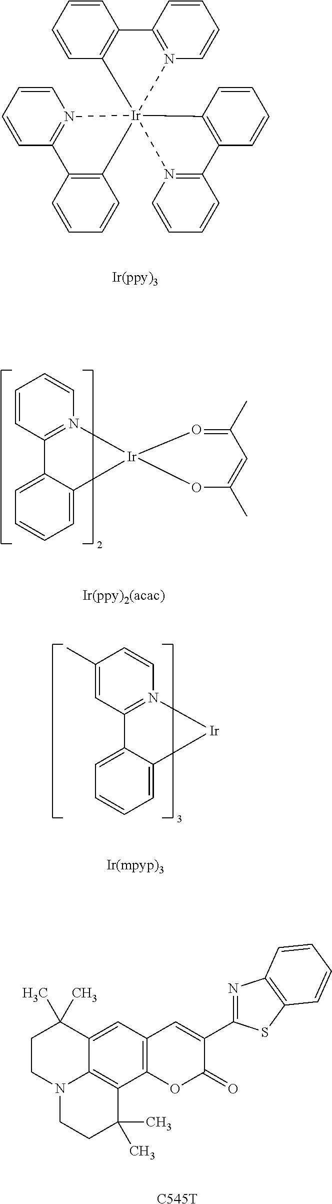

When the EML 15 includes both a host and a dopant, an amount of the dopant may be generally in a range from about 0.01 to about 15 parts by weight, based on 100 parts by weight of the host. However, the amount of the dopant is not limited thereto.

A thickness of the EML 15 may be in a range from about 100 Å to about 1,000 Å, e.g., in a range from about 200 Å to about 600 Å. When the thickness of the EML is within these ranges, the EML 15 may have good light emitting ability without a substantial increase in driving voltage.

Then, an ETL 17 may be formed on the EML 15 by vacuum deposition, spin coating, casting, or the like. When the ETL 17 is formed using vacuum deposition or spin coating, the deposition and coating conditions may be similar to those for the formation of the first HTL 14-1, though the deposition and coating conditions may vary depending on the compound that is used to form the ETL. A material for forming the ETL may be any known material that can stably transport electrons injected from an electron injection electrode (cathode). Examples of the known materials for forming the ETL are a quinoline derivative, such as tris(8-quinolinorate)aluminum (Alq3), TAZ, BAlq, beryllium bis(benzoquinolin-10-olate (Bebq₂), 9,10-di(naphthalene-2-yl)anthracene (ADN), Compound 201, and Compound 202, but are not limited thereto:

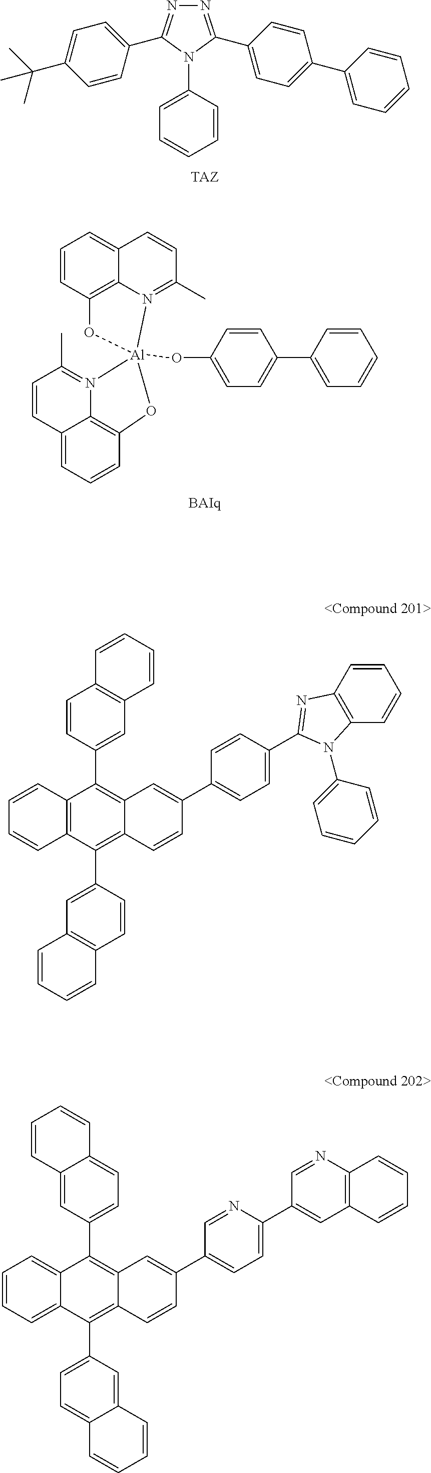

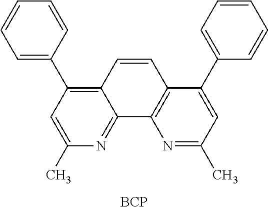 [SMILES: Cc1cc(-c2ccccc2)c2ccc3c(-c4ccccc4)cc(C)nc3c2n1 ; "BCP"]

A thickness of the ETL 17 may be in a range from about 100 Å to about 1,000 Å, e.g., in a range from about 150 Å to about 500 Å. When the thickness of the ETL 17 is within these ranges, the ETL may have satisfactory electron transporting ability without a substantial increase in driving voltage.

In an implementation the ETL may further include a metal-containing material, in addition to a suitable electron-transporting organic compound that is described above.

The metal-containing material may include a lithium (Li) complex. Non-limiting examples of the Li complex may include lithium quinolate (LiQ) and Compound 203, below.

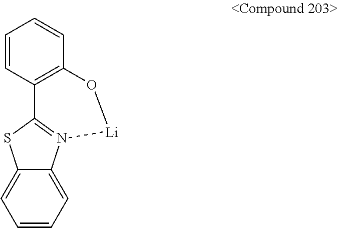

Also, an EIL 18, which facilitates injection of electrons from the cathode, may be formed on the ETL 17. A suitable electron-injecting material may be used to form the EIL.

Examples of materials for forming the EIL are LiF, NaCl, CsF, Li₂O, and BaO. The deposition conditions for forming the EIL 18 may be similar to those for the formation of the first HTL 14-1, though the deposition conditions may vary depending on the material that is used to form the EIL 18.

A thickness of the EIL 18 may be in a range from about 1 Å to about 100 Å, for example, in a range from about 3 Å to about 90 Å. When the thickness of the EIL is within these ranges, the EIL may have satisfactory electron injection ability without a substantial increase in driving voltage.

Finally, the second electrode 19 is disposed on the EIL 18. The second electrode 19 may be a cathode that is an electron injection electrode. Here, a material for forming the second electrode 19 may be a metal, an alloy, an electro-conductive compound, which has a low work function, or a mixture thereof. In this regard, the second electrode may be formed of lithium (Li), magnesium (Mg), aluminum (Al), aluminum-lithium (Al—Li), calcium (Ca), magnesium-indium (Mg—In), magnesium-silver (Mg—Ag), or the like, and may be formed as a thin film type transmission electrode. In some embodiments, to manufacture a top-emission light-emitting device, the transmission electrode may be formed of indium tin oxide (ITO) or indium zinc oxide (IZO).

Although the OLED of FIG. 1 is described above, the embodiments are not limited thereto. In some embodiments, the OLED may have wide variations, for example, the EIL 18 may be omitted depending on the needs.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example B1

To manufacture an anode, a Corning 15 Ω/cm² (1,200 Å) ITO glass substrate was cut to a size of 50 mm×50 mm×0.7 mm, sonicated in isopropyl alcohol and pure water each for about 5 minutes, and then cleaned by irradiation of ultraviolet rays for about 30 minutes and exposure to ozone. The Compound 40A was deposited on the resulting ITO glass substrate to form a first interlayer having a thickness of 50 Å. HT1 was deposited on the first interlayer to form a first hole transport layer having a thickness of 400 Å. After depositing the Compound 40A on the first hole transport layer to form a second interlayer having a thickness of 50 Å, NPB was deposited on the second interlayer to form a second hole transport layer having a thickness of 200 Å. Then, ADN (host) and BD (dopant) were vacuum-co-deposited on the second hole transport layer with a weight ratio of 97:3 to form an emission layer having a thickness of 200 Å. Next, Alq₃ was deposited on the emission layer to form an electron transport layer having a thickness of 300 Å, and then Al was deposited on the electron transport layer to form a second electrode (cathode) having a thickness of 1,200 Å to manufacture an organic-light emitting diode (OLED).

### Comparative Example B1

An OLED was manufactured in the same manner as in Example B 1, except that the first and second interlayers were not formed, and the thickness of the first and second hole transport layers were 450 Å and 250 Å, respectively.

### Comparative Example B2

An OLED was manufactured in the same manner as in Example B1, except that the first interlayer was not formed, and the thickness of the first hole transport layer was 450 Å.

### Comparative Example B3

An OLED was manufactured in the same manner as in Example B 1, except that the second interlayer was not formed, and the thickness of the second hole transport layer was 250 Å.

### Example G1

To manufacture an anode, a Corning 15 Ω/cm² (1,200 Å) ITO glass substrate was cut to a size of 50 mm×50 mm×0.7 mm, sonicated in isopropyl alcohol and pure water each for about 5 minutes, and then cleaned by irradiation of ultraviolet rays for about 30 minutes and exposure to ozone. The Compound 40A was deposited on the resulting ITO glass substrate to form a first interlayer having a thickness of 50 Å. HT1 was deposited on the first interlayer to form a first hole transport layer having a thickness of 600 Å. After depositing the Compound 40A on the first hole transport layer to form a second interlayer having a thickness of 50 Å, NPB was deposited on the second interlayer to form a second hole transport layer having a thickness of 200 Å. Then, ADN (host) and GD (dopant) were vacuum-co-deposited on the second hole transport layer with a weight ratio of 95:5 to form an emission layer having a thickness of 200 Å. Next, Alq₃ was deposited on the emission layer to form an electron transport layer having a thickness of 300 Å, and then Al was deposited on the electron transport layer to form a second electrode (cathode) having a thickness of 1,200 Å to manufacture an OLED.

### Comparative Example G1

An OLED was manufactured in the same manner as in Example G1, except that the first and second interlayers were not formed, and the thickness of the first and second hole transport layers were 650 Å and 250 Å, respectively.

### Comparative Example G2

An OLED was manufactured in the same manner as in Example G1, except that the first interlayer was not formed, and the thickness of the first hole transport layer was 650 Å.

### Comparative Example G3

An OLED was manufactured in the same manner as in Example G1, except that the second interlayer was not formed, and the thickness of the second hole transport layer was 250 Å.

TABLE 1

| | | | First hole | | Second hole | |
|---|---|---|---|---|---|---|
| | | | transport | Second | transport | |
| | Anode | First interlayer | layer | interlayer | layer | Emission layer |
| Example B1 | ITO | Compound 40A | HT1 | Compound 40A | NPB | ADN:BD(3 wt %) |
| | | (50 Å) | (400 Å) | (50 Å) | (200 Å) | (200 Å) |
| Comparative | ITO | — | HT1 | — | NPB | ADN:BD(3 wt %) |
| Example B1 | | | (450 Å) | | (250 Å) | (200 Å) |
| Comparative | ITO | — | HT1 | Compound 40A | NPB | ADN:BD(3 wt %) |
| Example B2 | | | (450 Å) | (50 Å) | (200 Å) | (200 Å) |
| Comparative | ITO | Compound 40A | HT1 | — | NPB | ADN:BD(3 wt %) |
| Example B3 | | (50 Å) | (400 Å) | | (250 Å) | (200 Å) |
| Example G1 | ITO | Compound 40A | HT1 | Compound 40A | NPB | ADN:GD(5 wt %) |
| | | (50 Å) | (600 Å) | (50 Å) | (200 Å) | (200 Å) |
| Comparative | ITO | — | HT1 | — | NPB | ADN:GD(5 wt %) |
| Example G1 | | | (650 Å) | | (250 Å) | (200 Å) |
| Comparative | ITO | — | HT1 | Compound 40A | NPB | ADN:GD(5 wt %) |
| Example G2 | | | (650 Å) | (50 Å) | (200 Å) | (200 Å) |
| Comparative | ITO | Compound 40A | HT1 | — | NPB | ADN:GD(5 wt %) |
| Example G3 | | (50 Å) | (600 Å) | | (250 Å) | (200 Å) |

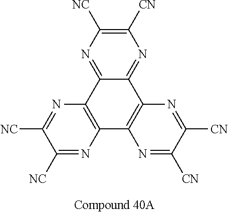 [SMILES: N#Cc1nc2c3nc(C#N)c(C#N)nc3c3nc(C#N)c(C#N)nc3c2nc1C#N]

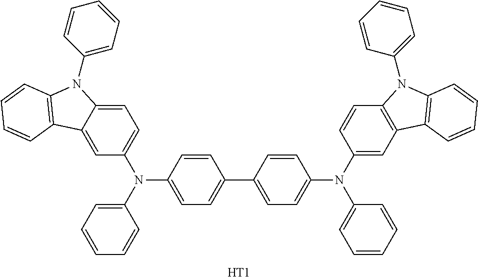 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; "HT1"]

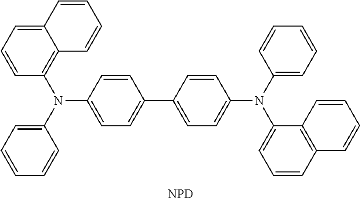 [SMILES: c1ccc(N(c2ccc(-c3ccc(N(c4ccccc4)c4cccc5ccccc45)cc3)cc2)c2cccc3ccccc23)cc1 ; "NPD"]

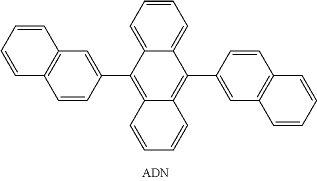 [SMILES: c1ccc2cc(-c3c4ccccc4c(-c4ccc5ccccc5c4)c4ccccc34)ccc2c1]

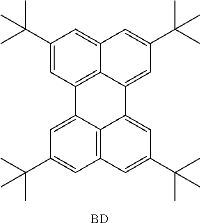 [SMILES: CC(C)(C)c1cc2cc(C(C)(C)C)cc3c4cc(C(C)(C)C)cc5cc(C(C)(C)C)cc(c(c1)c23)c54 ; "BD"]

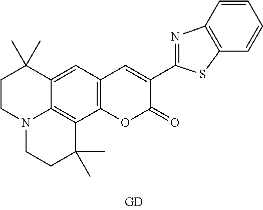 [SMILES: CC1(C)CCN2CCC(C)(C)c3c2c1cc1cc(-c2nc4ccccc4s2)c(=O)oc31]

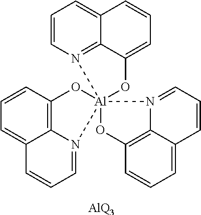

### Evaluation Example 1

Driving voltages, current densities, brightness, efficiencies, electrocities, and color purities characteristics of the OLED of the Examples and Comparative Examples above were measured using a 238 HIGH CURRENT SOURCE (available from KEITHLEY) a PR650 Spectroscan Source Measurement Unit. (available from Photo Research, Inc.). The results are shown in Table 2, below.

TABLE 2

| | Driving | Current | | | | | |
|---|---|---|---|---|---|---|---|
| | voltage | density | Brightness | Efficiency | Electricity | | |
| | (V) | (mA/cm²) | (cd/m²) | (cd/A) | (Im/W) | x | y |
| Example B1 | 4.2 | 9.9 | 400 | 3.9 | 2.9 | 0.147 | 0.071 |
| Comparative | 5.6 | 8.3 | 400 | 4.5 | 2.6 | 0.147 | 0.070 |
| Example B1 | | | | | | | |
| Comparative | 4.4 | 10 | 400 | 4.0 | 2.8 | 0.146 | 0.073 |
| Example B2 | | | | | | | |
| Comparative | 4.5 | 10 | 400 | 4.0 | 2.8 | 0.145 | 0.070 |
| Example B3 | | | | | | | |
| Example G1 | 3.9 | 9.9 | 3500 | 33 | 26 | 0.298 | 0.650 |
| Comparative | 4.6 | 9.2 | 3500 | 38 | 26 | 0.299 | 0.61 |
| Example G1 | | | | | | | |
| Comparative | 4.1 | 10 | 3500 | 34 | 26 | 0.299 | 0.651 |
| Example G2 | | | | | | | |
| Comparative | 4.1 | 10 | 3500 | 34 | 27 | 0.299 | 0.650 |
| Example G3 | | | | | | | |

Referring to Table 2, the OLED of Example B1 was found to have excellent characteristics, compared to the OLEDs of Comparative Examples B1 to B3. Also, the OLED of Example G1 was found to have excellent characteristics, compared to the OLEDs of Comparative Examples G1 to G3.

As described above, an organic light-emitting diode may help improve hole injecting ability and accordingly, its characteristics such as a driving voltage, a current density, luminance efficiency, and the like may be improved.

The embodiments provide an OLED exhibiting improved driving voltage characteristics and power efficiency characteristics.

While the embodiments of the present invention has been particularly shown and described with reference to exemplary embodiments thereof, it will be understood by those of ordinary skill in the art that various changes in form and details may be made therein without departing from the spirit and scope of the embodiments of the present invention as defined by the following claims.

What is claimed is:

1. An organic light-emitting diode, comprising:
a substrate;
a first electrode on the substrate;
a second electrode disposed opposite to the first electrode;
an emission layer disposed between the first electrode and second electrode; and
a first interlayer, a first hole transport layer, a second interlayer and a second hole transport layer disposed between the first electrode and the emission layer,
wherein the first interlayer, the first hole transport layer, the second interlayer, and the second hole transport layer are stacked from the first electrode in order, and
wherein the first interlayer and the second interlayer each independently include an n-type semiconductor material.

2. The organic light-emitting diode as claimed in claim 1, wherein:
the first electrode and the first interlayer are directly in contact,
the first interlayer and the first hole transport layer are directly in contact,
the first hole transport layer and the second interlayer are directly in contact,
the second interlayer and the second hole transport layer are directly in contact, and
the second hole transport layer and the emission layer are directly in contact.

3. The organic light-emitting diode as claimed in claim 1, wherein the first interlayer and the second interlayer each independently include at least one of a hexaazatriphenylene-based compound and a cyano group-containing compound.

4. The organic light-emitting diode as claimed in claim 3, wherein at least one of the first interlayer and the second interlayer include the hexaazatriphenylene-based compound, the hexaazatriphenylene-based compound being represented by Formula 40 below: 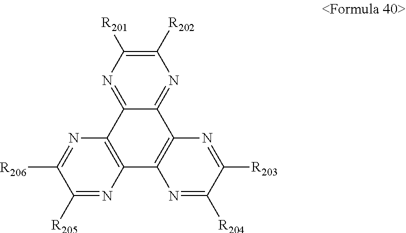
wherein, in Formula 40,
R₂₀₁ to R₂₀₆ are each independently selected from:
a hydrogen atom, a deuterium atom, a halogen atom, a cyano group (—CN), a nitro group (—NO₃), —SO₂R₂₁₀, —SOR₂₁₁, —SO₃R₂₁₂, —COOR₂₁₃, —CONHR₂₁₄, —CONR₂₁₅R₂₁₆, a C₁-C₂₀ alkyl group, a C₁-C₂₀ alkoxy group, a C₂-C₂₀ alkenyl group, a C₆-C₃₀ aryl group, a C₂-C₃₀ heteroaryl group; or
a C₁-C₂₀ alkyl group, a C₁-C₂₀ alkoxy group, a C₂-C₂₀ alkenyl group, a C₆-C₃₀ aryl group, or a C₂-C₃₀ heteroaryl group, each substituted with at least one of a deuterium atom, a halogen atom, a cyano group (—CN), or a nitro group (—NO₃);
R₂₁₀ to R₂₁₆ are each independently selected from a C₁-C₂₀ alkyl group, a C₁-C₂₀ alkoxy group, a C₂-C₂₀ alkenyl group, a C₆-C₃₀ aryl group, or a C₂-C₃₀ heteroaryl group.

5. The organic light-emitting diode as claimed in claim 4, wherein:
R₂₀₁ to R₂₀₆ are each independently selected from:
a hydrogen atom, a deuterium atom, a halogen atom, a cyano group (—CN), a nitro group (—NO₃), —SO₂R₂₁₀, —SOR₂₁₁, —SO₃R₂₁₂, —COOR₂₁₃, —CONHR₂₁₄, —CONR₂₁₅R₂₁₆, a C₁-C₁₀ alkyl group, a C₁-C₁₀ alkoxy group, a C₂-C₁₀ alkenyl group, a phenyl group, a naphthyl group, an anthryl group, a pyridinyl group, a pyrimidinyl group, a triazinyl group; or
a C₁-C₂₀ alkyl group, a C₁-C₂₀ alkoxy group, a phenyl group, a naphthyl group, an anthryl group, a pyridinyl group, a pyrimidinyl group, or a triazinyl group, each substituted with at least one of a deuterium atom, a halogen atom, a cyano group (—CN), or a nitro group (—NO₃); and
R₂₁₀ to R₂₁₆ are each independently selected from a C₁-C₁₀ alkyl group, a C₁-C₁₀ alkoxy group, a C₂-C₁₀ alkenyl group, a phenyl group, a naphthyl group, an anthryl group, a pyridinyl group, a pyrimidinyl group, or a triazinyl group.

6. The organic light-emitting diode as claimed in claim 4, wherein the hexaazatriphenylene-based compound represented by Formula 40 is one of Compounds 40A to 40E below:

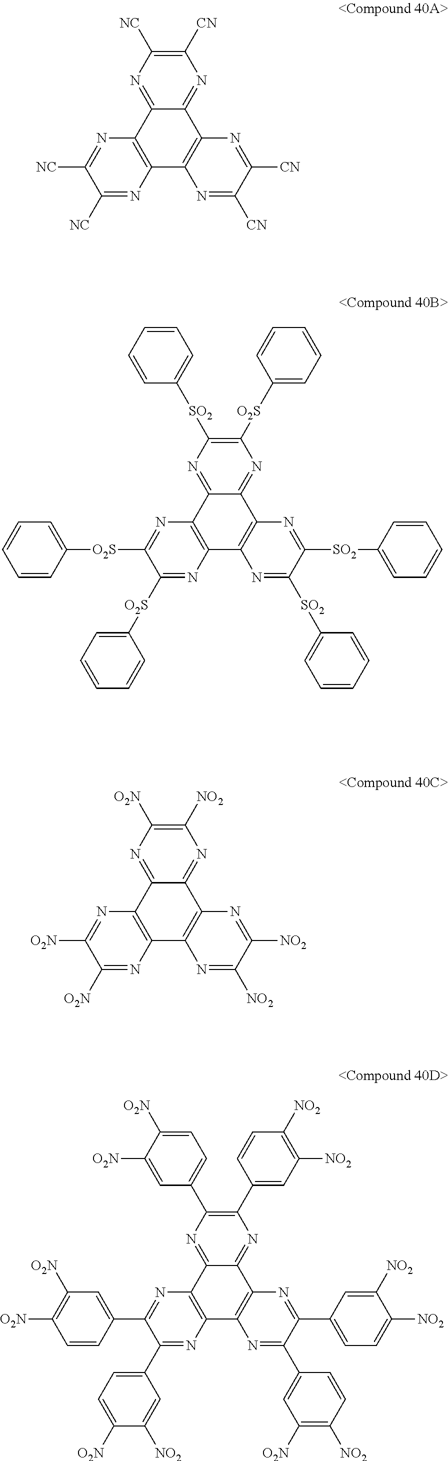

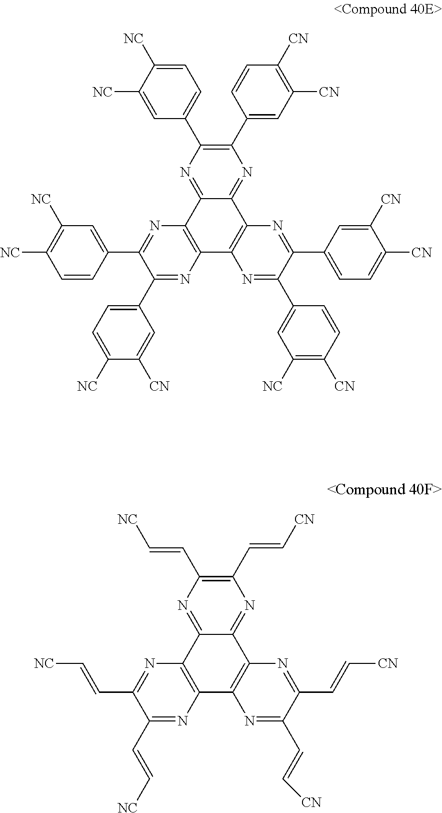 [SMILES: N#Cc1ccc(-c2nc3c4nc(-c5ccc(C#N)c(C#N)c5)c(-c5ccc(C#N)c(C#N)c5)nc4c4nc(-c5ccc(C#N)c(C#N)c5)c(-c5ccc(C#N)c(C#N)c5)nc4c3nc2-c2ccc(C#N)c(C#N)c2)cc1C#N ; N#C/C=C/c1nc2c3nc(/C=C/C#N)c(/C=C/C#N)nc3c3nc(/C=C/C#N)c(/C=C/C#N)nc3c2nc1/C=C/C#N]

7. The organic light-emitting diode as claimed in claim 3, wherein at least one of the first interlayer and the second interlayer include the cyano group-containing compound, the cyano group-containing compound being represented by one of Formulae 1 to 20 below: 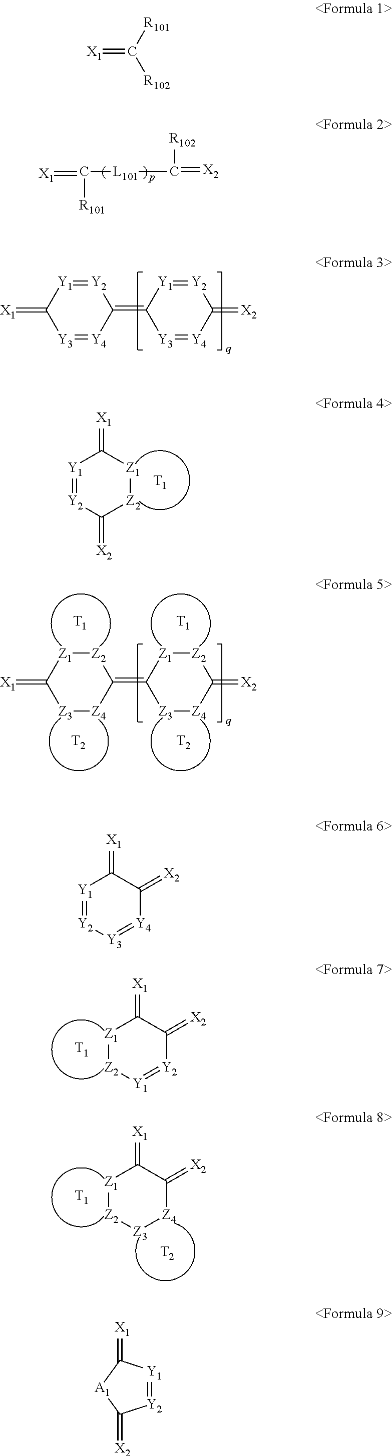 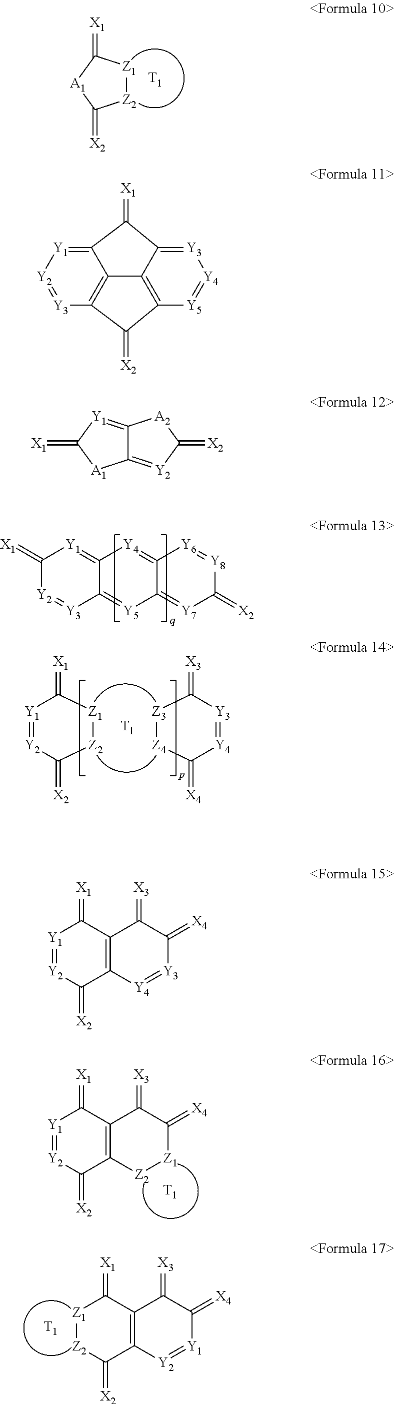 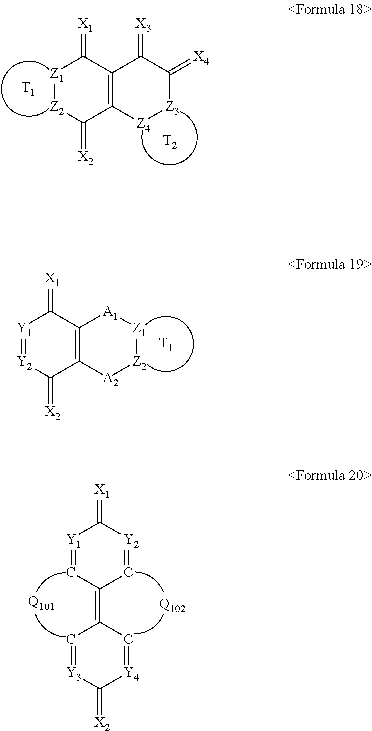 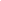
wherein, in Formulae 1 to 20,
X₁ to X₄ are each independently represented by one of Formulae 30A to 30D below; 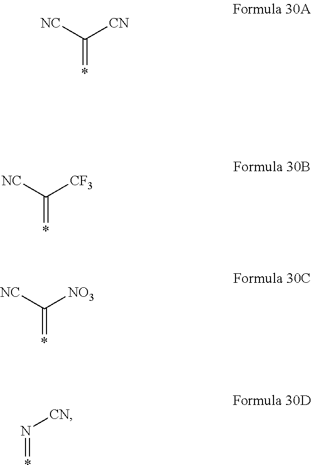
Y₁ to Y₈ are each independently selected from N or C(R₁₀₃);
Z₁ to Z₄ are each independently selected from C or N;
A₁ and A₂ are each independently selected from —O—, —S—, —N(R₁₀₄), or —C(R₁₀₅)(R₁₀₆)—;
Q₁₀₁ and Q₁₀₂ are each independently selected from a C₂-C₁₀ alkylene group; a C₂-C₁₀ alkenylene group; or a C₂-C₁₀ alkylene group or C₂-C₁₀ alkenylene group, each substituted with at least one substituent selected from a halogen atom, a cyano group, a hydroxyl group, a C₁-C₁₀ alkyl group, or a C₁-C₁₀ alkoxy group;
T₁ and T₂ are each independently selected from a C₆-C₃₀ aromatic ring system; a C₂-C₃₀ heteroaromatic ring system; or a C₆-C₃₀ aromatic ring system or C₂-C₃₀ heteroaromatic ring system, each substituted with at least one substituent selected from a halogen atom, a cyano group, a hydroxyl group, a C₁-C₁₀ alkyl group, or a C₁-C₁₀ alkoxy group;
p is an integer from 1 to 10;
q is an integer from 0 to 10;
R₁₀₁ to R₁₀₆ are each independently selected from a hydrogen atom, a halogen atom, a cyano group, a hydroxyl group, a C₁-C₁₀ alkyl group, a C₁-C₁₀ alkoxy group; a C₁-C₁₀ alkyl group or C₁-C₁₀ alkoxy group, each substituted with at least one substituent selected from a halogen atom, a cyano group, a hydroxyl group, a C₆-C₁₄ aryl group, or a C₂-C₁₄ heteroaryl group; 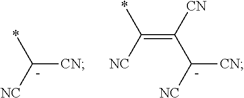 [SMILES: *[C-](C#N)C#N ; */C(C#N)=C(\C#N)[C-](C#N)C#N]
or —N(R₁₀₇)(R₁₀₈),
R₁₀₇ and R₁₀₈ are each independently selected from a hydrogen atom, a C₁-C₁₀ alkyl group, a phenyl group, or a biphenyl group; and
L₁₀₁ is one of a C₆-C₁₄ arylene group or a C₂-C₁₄ heteroarylene group; C₂-C₁₀ alkenylene group, C₆-C₁₄ arylene group, or C₂-C₁₄ heteroarylene group, each substituted with at least one substituent selected from a halogen atom, a cyano group, a hydroxyl group, a C₁-C₁₀ alkyl group, or a C₁-C₁₀ alkoxy group.

8. The organic light-emitting diode as claimed in claim 7, wherein R₁₀₃ is one of a hydrogen atom, a halogen atom, a cyano group, a C₁-C₁₀ alkyl group, a C₁-C₁₀ alkoxy group, or a C₁-C₁₀ alkyl group or C₁-C₁₀ alkoxy group, each substituted with at least one substituent selected from a halogen atom, a cyano group, a phenyl group, a naphthyl group, an anthryl group, a pyridinyl group, a thiophenyl group, and a benzophenyl group; or —N(R₁₀₇)(R₁₀₈), and
wherein R₁₀₇ and R₁₀₈ are each independently selected from a hydrogen atom, a C₁-C₁₀ alkyl group, a phenyl group, or a biphenyl group.

9. The organic light-emitting diode as claimed in claim 7, wherein R₁₀₁ and R₁₀₂ are each independently selected from a cyano group,

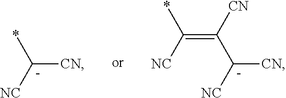 [SMILES: *[C-](C#N)C#N ; "or" ; */C(C#N)=C(\C#N)[C-](C#N)C#N]

10. The organic light-emitting diode as claimed in claim 7, wherein Q₁₀₁ and Q₁₀₂ are each independently selected from an ethylene group, a propylene group, an ethenylene group, a prophenylene group, or an ethylene group, propylene group, ethenylene group, or prophenylene group, each substituted with at least one substituent selected from a halogen atom, a cyano group, or a hydroxyl group;
T₁ and T₂ are each independently selected from benzene, naphthalene, anthracene, thiophene, thiadiazole, oxadiazole; or benzene, naphthalene, anthracene, thiophene, thiadiazole, or oxadiazole, each substituted with at least one substituent selected from a halogen atom, a cyano group, a C₁-C₁₀ alkyl group, or a C₁-C₁₀ alkoxy group;
L₁₀₁ is one of a thiophenylene group, a benzophenylene group; or a thiophenylene group or benzophenylene group, each substituted with at least one substituent selected from a halogen atom, a cyano group, or a C₁-C₁₀ alkyl group.

11. The organic light-emitting diode as claimed in claim 1, wherein a compound included in the first interlayer is the same as a compound included in the second interlayer.

12. The organic light-emitting diode as claimed in claim 1, wherein a thickness of the first interlayer and a thickness of the second interlayer are each independently in a range from about 5 Å to about 100 Å.

13. The organic light-emitting diode as claimed in claim 1, wherein the first and second hole transport layers each independently include at least one compound selected from the group of a compound represented by Formula 41, below, or a compound represented by Formula 42, below: 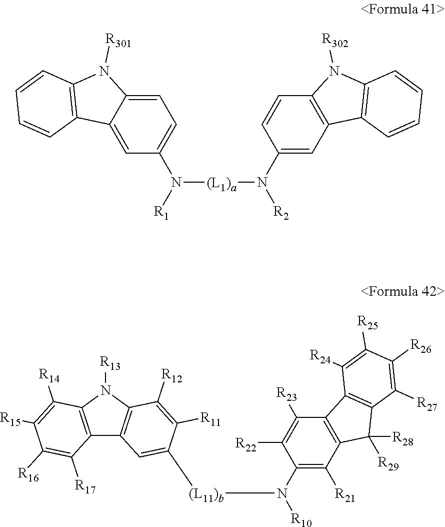
wherein, in Formulae 41 and 42,
R₁₀ is represented by —(Ar₁)ₙ—Ar₂;
R₁₆ is represented by —(Ar₁₁)ₘ—Ar₁₂;
Ar₁, Ar₁₁, L₁, and L₁₁ are each independently selected from a substituted or unsubstituted C₁-C₃₀ alkylene group, a substituted or unsubstituted C₂-C₃₀ alkenylene group, a substituted or unsubstituted C₆-C₃₀ arylene group, a substituted or unsubstituted C₂-C₃₀ heteroarylene group, or a group represented by —N(Q₁)-;
n, m, a, and b are each independently an integer from 0 to 10;
R₁ to R₃, R₁₁ to R₁₅, R₁₇, R₁₈, R₂₁ to R₂₉, Ar₂, Ar₁₂, and Q₁ are each independently selected from a hydrogen atom, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthio group, a substituted or unsubstituted C₆-C₃₀ aryl group, C₂-C₃₀ heteroaryl group, or a group represented by —N(Q₂)(Q₃);
Q₂ and Q₃ are each independently selected from a hydrogen atom, a halogen atom, a hydroxyl group, a cyano group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₁-C₃₀ alkylthio group, a substituted or unsubstituted C₆-C₃₀ aryl group, or a C₂-C₃₀ heteroaryl group;
R₃₀₁ and R₃₀₂ are each independently a substituted or unsubstituted C₆-C₃₀ aryl group; and
Ar₁ in number of n in —(Ar₁)ₙ— are identical to or different from each other, in Ar₁₁ in number of m —(Ar₁₁)ₘ— are identical to or different from each other, L₁ in number of a in -(L₁)ₐ- are identical to or different each other, and L₁₁ in number of b in -(L₁₁)_{b}- are identical to or different from each other.

14. The organic light-emitting diode as claimed in claim 13, wherein:
Ar₁ and Ar₁₁ are each independently selected from:
a C₁-C₁₀ alkylene group, a phenylene group, a naphthylene group, an anthrylene group, a fluorenylene group, a carbazolylene group, a pyrazolylene group, a pyridinylene group, a triazinylene group, —N(Q₁)-; or
a C₁-C₁₀ alkylene group, phenylene group, naphthylene group, anthrylene group, fluorenylene group, carbazolylene group, pyrazolylene group, pyridinylene group, or triazinylene group, each substituted with at least one substituent selected from a halogen atom, a cyano group, a hydroxyl group, a C₁-C₁₀ alkyl group, a C₁-C₁₀ alkoxy group, a phenyl group, a naphthyl group, or an anthryl group; and
Q₁ is selected from:
a hydrogen atom, C₁-C₁₀ alkyl group, a phenyl group, a naphthyl group, a carbazolylene group, a fluorenyl group; or
a C₁-C₁₀ alkyl group, C₁-C₁₀ alkoxy group, phenyl group, naphthyl group, carbazolylene group, or fluorenyl group, each substituted with at least one substituent selected from a halogen atom; a cyano group, a hydroxyl group, a C₁-C₁₀ alkyl group, a C₁-C₁₀ alkoxy group, a phenyl group, a naphthyl group, or an anthryl group.

15. The organic light-emitting diode as claimed in claim 13, wherein Ar₂ and Ar₁₂ are each independently selected from:
a hydrogen atom, a C₁-C₁₀ alkyl group, a phenyl group, a naphthyl group, a carbazolyl group, a fluorenyl group, a pyrenyl group;
a C₁-C₁₀ alkyl group, C₁-C₁₀ alkoxy group, phenyl group, anaphthyl group, carbazolyl group, fluorenyl group, or pyrenyl group, each substituted with at least one substituent selected from a halogen atom, a cyano group, a hydroxyl group, a C₁-C₁₀ alkyl group, a C₁-C₁₀ alkoxy group, a phenyl group, a naphthyl group, or an anthryl group; or
—N(Q₂)(Q₃);
wherein Q₂ and Q₃ are each independently selected from a hydrogen atom, a methyl group, an ethyl group, a phenyl group, a methylphenyl group, a biphenyl group, a naphthyl group, or a methylnaphthyl group.

16. The organic light-emitting diode as claimed in claim 13, wherein:
the first hole transport layer includes a first compound represented by Formula 41, and
the second hole transport layer includes a second compound represented by Formula 42.

17. The organic light-emitting diode as claimed in claim 13, wherein:
the first hole transport layer includes one of Compounds 301 to 308, below, and
the second hole transport layer includes one of Compounds 309 to 320, below:

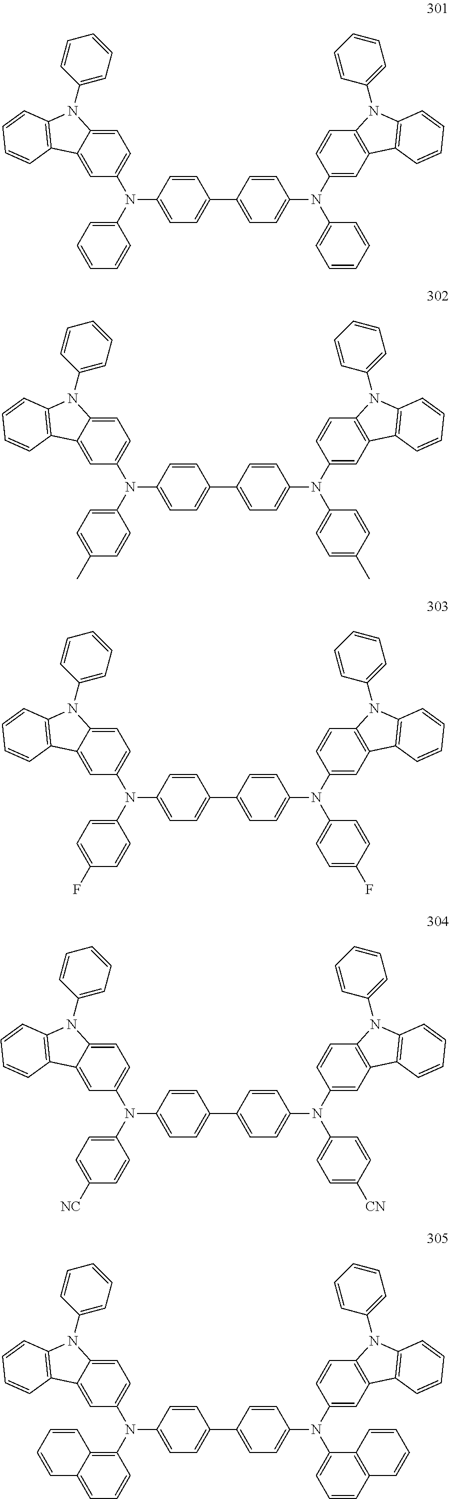

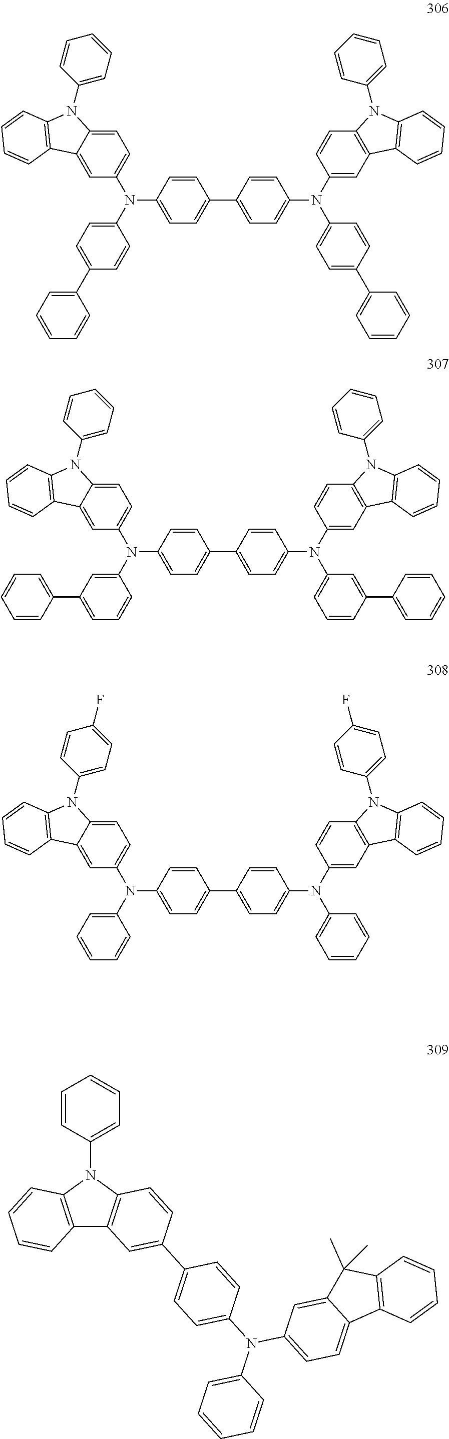 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; CC1(C)c2ccccc2-c2ccc(N(c3ccccc3)c3ccc(-c4ccc5c(c4)c4ccccc4n5-c4ccccc4)cc3)cc21]

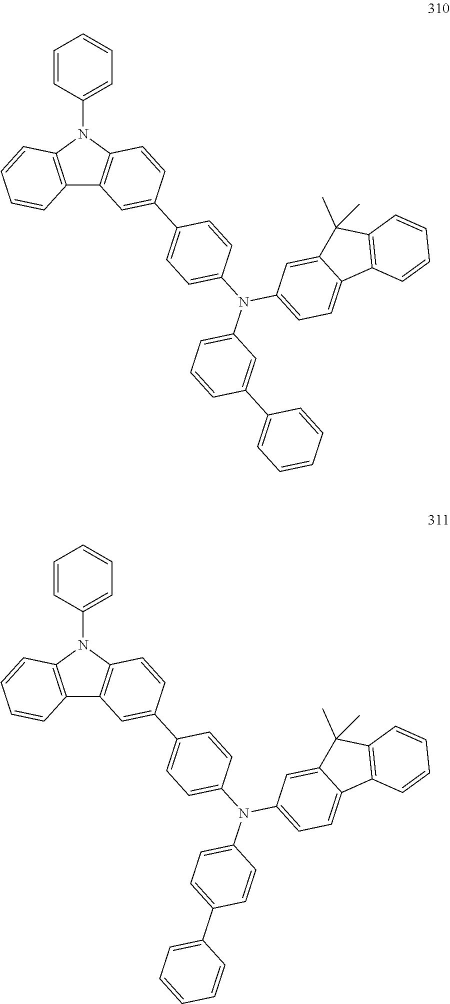 [SMILES: CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

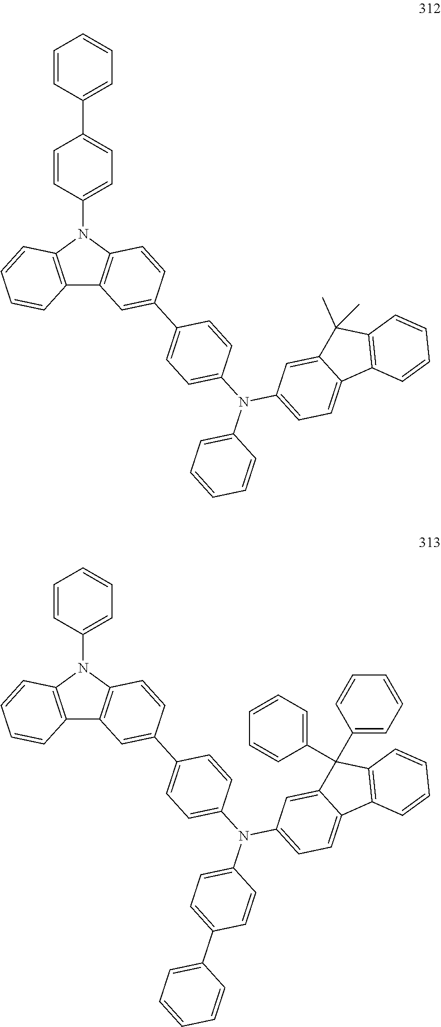 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

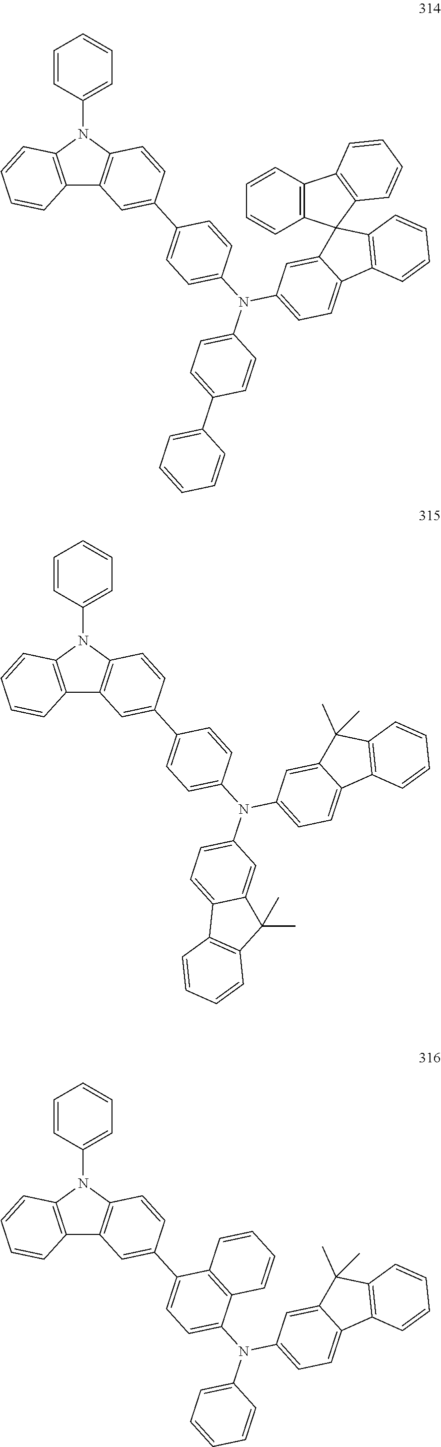 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

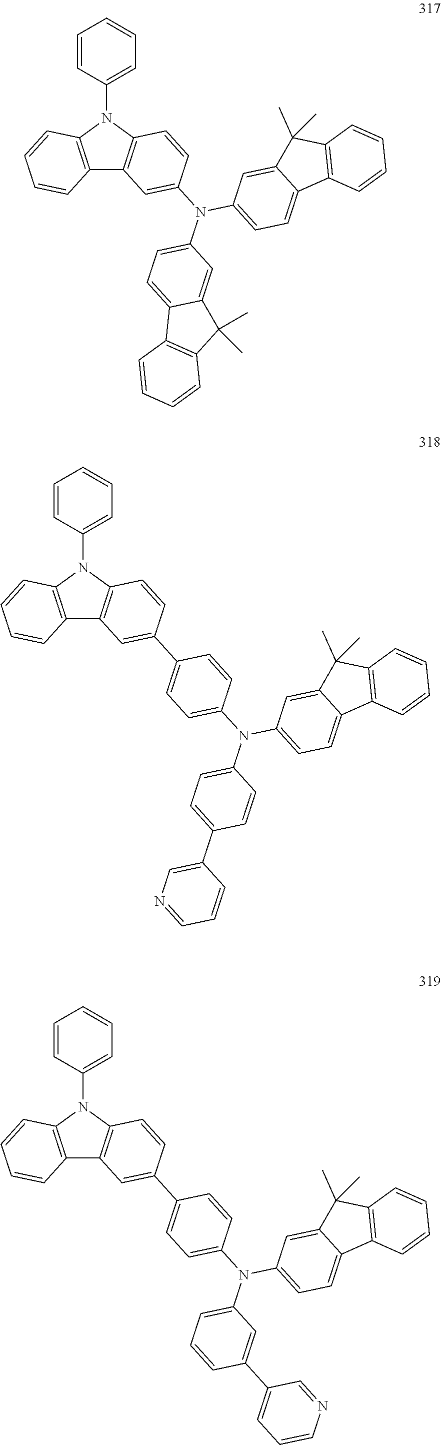 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

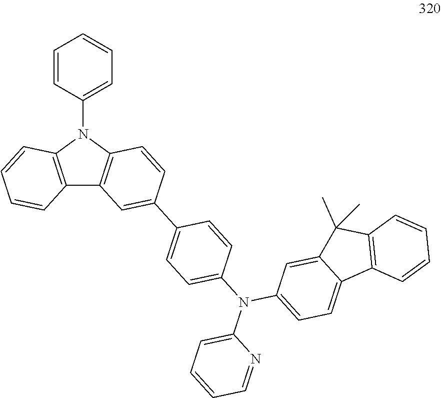 [SMILES: CC1(C)c2ccccc2-c2ccc(N(c3ccc(-c4ccc5c(c4)c4ccccc4n5-c4ccccc4)cc3)c3ccccn3)cc21]

18. The organic light-emitting diode as claimed in claim 13, wherein a thickness of the first hole transport layer and a thickness of the second hole transport layer are each independently in a range of about 10 Å to about 2,000 Å.

19. The organic light-emitting diode as claimed in claim 1, wherein:
materials included in the first hole transport layer and second hole transport layer are not included in the first interlayer and second interlayer; and
materials included in the first interlayer and second interlayer are not included in the first hole transport layer and second hole transport layer.
